(19) United States
(12) Patent Application Publication
(10) Pub. No.: US 2022/0069164 A1
(43) Pub. Date: Mar. 3, 2022

(54) LIGHT-EMITTING ELEMENT, METHOD OF MANUFACTURING LIGHT-EMITTING ELEMENT, AND DISPLAY DEVICE INCLUDING LIGHT-EMITTING ELEMENT

(71) Applicant: Samsung Display Co., LTD., Yongin-si (KR)

(72) Inventors: Seung Geun LEE, Yongin-si (KR); Byung Ju LEE, Yongin-si (KR); Won Sik OH, Yongin-si (KR); Seung A LEE, Yongin-si (KR)

(73) Assignee: Samsung Display Co., LTD., Yongin-si (KR)

(21) Appl. No.: 17/327,168

(22) Filed: May 21, 2021

(30) Foreign Application Priority Data
Aug. 31, 2020 (KR) 10-2020-0110405

(51) Int. Cl. H01L 33/38; H01L 33/30; H01L 33/00; H01L 27/15

(52) U.S. Cl. CPC H01L 33/382; H01L 27/156; H01L 33/0062; H01L 33/305

(57) ABSTRACT

A light-emitting element includes a first end portion and a second end portion disposed in a length direction of the light-emitting element, a first semiconductor layer disposed at the first end portion, an active layer disposed on the first semiconductor layer, a second semiconductor layer disposed on the active layer, a first barrier layer disposed between the active layer and the first semiconductor layer and including a first region and a second region, and an insulating film that surrounds an outer circumferential surface of each of the first semiconductor layer, the active layer, the first barrier layer, and the second semiconductor layer. The first region includes a semiconductor layer having an aluminum composition higher than an aluminum composition of the first semiconductor layer, the active layer, and the second semiconductor layer. The second region includes an oxide layer.

### CROSS-REFERENCE TO RELATED APPLICATION(S)

This application claims priority to and benefits of Korean Patent Application No. 10-2020-0110405 under 35 U.S.C. § 119, filed on Aug. 31, 2020 in the Korean Intellectual Property Office, the entire contents of which are incorporated herein by reference.

### BACKGROUND

### 1. Technical Field

The disclosure relates to a light-emitting element, a method of manufacturing the light-emitting element, and a display device including the light-emitting element.

### 2. Description of the Related Art

As interests in information displays and demands on using portable information media increase, research and commercialization on display devices are actively performed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides a light-emitting element in which a barrier layer including an oxide layer is disposed on and below an active layer, thereby minimizing a surface leakage current due to damage to a surface exposed during a manufacturing process to improve luminous efficiency, and a method of manufacturing the same.

The disclosure also provides a display device including the above-described light-emitting element.

A light-emitting element may include a first end portion and a second end portion disposed in a length direction of the light-emitting element; a first semiconductor layer disposed at the first end portion; an active layer disposed on the first semiconductor layer; a second semiconductor layer disposed on the active layer; a first barrier layer disposed between the active layer and the first semiconductor layer, the first barrier layer including a first region and a second region; and an insulating film that surrounds an outer circumferential surface of each of the first semiconductor layer, the active layer, the first barrier layer, and the second semiconductor layer. The first region of the first barrier layer may include a semiconductor layer having an aluminum composition higher than an aluminum composition of the first semiconductor layer, the active layer, and the second semiconductor layer. The second region of the first barrier layer may include an oxide layer.

In an embodiment, the first semiconductor layer may include an n-type semiconductor layer doped with an n-type dopant, the second semiconductor layer may include a p-type semiconductor layer doped with a p-type dopant. The active layer and the first barrier layer may be semiconductor layers that may not be doped with the n-type dopant or the p-type dopant.

In an embodiment, the light-emitting element may further include a second barrier layer disposed between the second semiconductor layer and the active layer, the second barrier layer including a third region and a fourth region. The second barrier layer may be a semiconductor layer which may not be doped with the n-type dopant or the p-type dopant.

In an embodiment, the third region of the second barrier layer may include a second semiconductor layer having an aluminum composition higher than the aluminum composition of the first semiconductor layer, the active layer, and the second semiconductor layer, and the fourth region of the second barrier layer may include an oxide layer. The third region and the fourth region may have a same thickness in the length direction of the light-emitting element.

In an embodiment, the second region and the fourth region may have a same width or different widths in a direction intersecting the length direction of the light-emitting element. The second region and the fourth region may have a same thickness or different thicknesses in the length direction of the light-emitting element.

In an embodiment, the first barrier layer and the second barrier layer may include a same material.

In an embodiment, the first region of the first barrier layer and the third region of the second barrier layer may include an AlInP layer including aluminum, indium, and phosphorus or an AlGaAs layer including aluminum, gallium, and arsenic.

In an embodiment, the first region of the first barrier layer and the second region of the first barrier layer may have a same thickness in the length direction of the light-emitting element.

In an embodiment, the light-emitting element may further include an electrode disposed on the second semiconductor layer at the second end portion of the light-emitting element.

The above-described light-emitting element may be manufactured through a method of manufacturing a light-emitting element that may include forming a first semiconductor layer, a first barrier layer, an active layer, a second barrier layer, a second semiconductor layer, and an electrode on a substrate to form a light-emitting stack; vertically etching the light-emitting stack to form at least one light-emitting stack pattern and externally exposing one region of the first semiconductor layer; performing heat treatment on the at least one light-emitting stack pattern so that each of the first barrier layer and the second barrier layer includes a first region and a second region, the first region and the second region including different materials; forming an insulating material layer on the at least one light-emitting stack pattern and vertically etching the insulating material layer to form an insulating film surrounding a surface of the light-emitting stack pattern; and separating the at least one light-emitting stack pattern surrounded by the insulating film from the substrate to form a light-emitting element. The light-emitting element may include the first semiconductor layer, the first barrier layer, the active layer, the second barrier layer, the second semiconductor layer, and the electrode disposed in a length direction of the light emitting element.

In an embodiment, the first region of each of the first barrier layer and second barrier layer may include a semiconductor layer having an aluminum composition higher than an aluminum composition of the first semiconductor layer, the active layer, and the second semiconductor layer, and the second region of each of the first barrier layer and the second barrier layer may include an oxide layer.

In an embodiment, the first semiconductor layer may include an n-type semiconductor layer doped with an n-type dopant, the second semiconductor layer may include a p-type semiconductor layer doped with a p-type dopant, and the first barrier layer, the active layer, and the second barrier layer may be semiconductor layers which may not be doped with the n-type dopant or the p-type dopant.

In an embodiment, the second region of the first barrier layer and the second region of the second barrier layer may have a same width or different widths in a direction intersecting the length direction of the light-emitting element.

In an embodiment, the second region of the first barrier layer and the second region of the second barrier layer have a same thickness or different thicknesses in the length direction of the light-emitting element.

In an embodiment, the forming of the light-emitting stack may include forming the first semiconductor layer on the substrate; forming the first barrier layer on the first semiconductor layer; forming the active layer on the first barrier layer; forming the second barrier layer on the active layer; forming the second semiconductor layer on the second barrier layer; and forming the electrode on the second semiconductor layer.

In an embodiment, the first region of each of the first barrier layer and the second barrier layer may include an AlInP layer including aluminum, indium, and phosphorus or an AlGaAs layer including aluminum, gallium, and arsenic.

In an embodiment, the first barrier layer and the second barrier layer may include a same material, and the first region of each of the first barrier layer and the second barrier layer may have a same thickness as the second region of the respective barrier layer.

A display device according to an embodiment may include a first electrode and a second electrode disposed on a substrate in a first direction and extending in a second direction different from the first direction, the first electrode and the second electrode being spaced apart from each other; and a plurality of light-emitting elements disposed between the first electrode and the second electrode. Each of the plurality of light-emitting elements may include a first end portion and a second end portion disposed in a length direction of the light-emitting element; a first semiconductor layer disposed at the first end portion; a first barrier layer disposed on the first semiconductor layer and including a first region and a second region; an active layer disposed on the first barrier layer; a second barrier layer disposed on the active layer and including a third region and a fourth region; a second semiconductor layer disposed on the second barrier layer; a third electrode disposed on the second semiconductor layer; and an insulating film surrounding an outer circumferential surface of each of the first semiconductor layer, the first barrier layer, the active layer, the second barrier layer, the second semiconductor layer, and the third electrode.

In an embodiment, the first region and the third region may include a semiconductor layer having an aluminum composition higher than an aluminum composition of the first semiconductor layer, the active layer, and the second semiconductor layer, and the second region and the fourth region may include an oxide layer.

In an embodiment, the first semiconductor layer may include an n-type semiconductor layer doped with an n-type dopant, the second semiconductor layer may include a p-type semiconductor layer doped with a p-type dopant, the first barrier layer, the active layer, and the second barrier layer may be undoped regions, the first region and the second region may have a same thickness in the length direction of the light-emitting element, and the third region and the fourth region may have a same thickness in the length direction of the light-emitting element.

In an embodiment, the display device may further include a first contact electrode disposed on the first electrode and one of the first end portion and the second end portion of each of the plurality of light-emitting elements; and a second contact electrode disposed on the second electrode and the other of the first end portion and the second end portion of each of the plurality of light-emitting elements, wherein the first contact electrode may be electrically connected to the first electrode, and the second contact electrode may be electrically connected to the second electrode.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view illustrating a light-emitting element according to an embodiment.

FIG. 2 is a schematic cross-sectional view of the light-emitting element of FIG. 1.

FIGS. 3 to 16 are schematic cross-sectional views sequentially illustrating a method of manufacturing the light-emitting element of FIGS. 1 and 2.

FIGS. 17 and 18 are schematic perspective views illustrating light-emitting elements according to embodiments.

FIG. 19 illustrates a display device according to an embodiment, and for example, is a schematic plan view of a display device using the light-emitting element illustrated in FIGS. 1 and 2 as a light source.

FIG. 20 is an equivalent circuit diagram illustrating an electrical connection relationship between components included in one pixel illustrated in FIG. 19 according to an embodiment.

FIG. 21 is a schematic plan view illustrating one pixel of pixels illustrated in FIG. 19.

FIG. 22 is a schematic cross-sectional view taken along line I-I′ of FIG. 21.

FIG. 23 is a schematic enlarged schematic cross-sectional view of portion EA1 of FIG. 22.

FIG. 24 is a schematic enlarged schematic cross-sectional view of portion EA2 of FIG. 23.

FIG. 25 is a schematic cross-sectional view taken along line II-II′ of FIG. 21.

FIG. 26 is a schematic plan view illustrating a pixel according to an embodiment.

FIG. 27 is a schematic cross-sectional view taken along line III-III′ of FIG. 26.

FIG. 28 is a schematic cross-sectional view corresponding to line III-III′ of FIG. 27 which illustrates a bank pattern of FIG. 27 that is implemented according to an embodiment.

FIG. 29 is a schematic cross-sectional view corresponding to line III-III′ of FIG. 26 which illustrates first and second contact electrodes of FIG. 27 that are implemented according to an embodiment.

### DETAILED DESCRIPTION OF THE EMBODIMENTS

While the disclosure includes various modifications and alternative embodiments, embodiments thereof will be described and illustrated by way of example in the accompanying drawings. However, it should be understood that the disclosure is not limited to the embodiments disclosed, and, on the contrary, the disclosure is intended to cover all modifications, equivalents, and alternatives falling within the spirit and scope of the disclosure.

Like numbers refer to like elements throughout the drawings. In the accompanying drawings, the sizes of structures and elements may be exaggerated for clarity. Although the terms “first”, “second”, etc. are used herein to describe various elements, these elements should not be limited by these terms. These terms are used only for the purpose of distinguishing one element from another. For example, without departing from the scope of the disclosure, a first element could be termed a second element, and similarly a second element could be also termed a first element. A single form of an expression or element includes plural expressions or elements unless otherwise stated.

As used herein, the term “and/or” includes any and all combinations of one or more of the associated listed items.

The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.

It will be understood that the terms “comprises” and/or “comprising,” or “includes” and/or “including,” or “have” and/or “having” and all variations thereof when used in this specification, specify the presence of stated features, integers, steps, operations, elements, components, and/or combinations thereof but do not preclude the presence or addition of one or more other features, integers, steps, operations, elements, components, and/or combinations thereof. In addition, when a layer, a film, an area, or a plate is referred to as being “on” or “under” another layer, another film, another area, or another plate, it can be “directly” or “indirectly” on the other layer, film, area, plate, or one or more intervening layers may also be present. Further, in the disclosure, when a part of a layer, a film, an area, a plate, and the like is formed on another part, a direction, in which the part is formed, is not limited only to an upwards direction, and includes a lateral direction or a downward direction. On the contrary, it will be understood that when an element such as a layer, film, area, or plate is referred to as being “beneath” another element, it can be directly beneath the other element or intervening elements may also be present.

In the disclosure, when it is described that an element (such as a first element) is “operatively or communicatively coupled with/to” or “connected” to another element (such as a second element), the element can be directly connected to the other element or can be connected to the other element through another element (for example, a third element). On the contrary, when it is described that an element (for example, a first element) is “directly connected” or “directly coupled” to another element (for example, a second element), it means that there is no intermediate element (for example, a third element) between the element and the other element.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first element may directly or indirectly oppose a second element. In a case in which a third element intervenes between the first and second element, the first and second element may be understood as being indirectly opposed to one another, although still facing each other. When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments necessary for those skilled in the art to understand the contents of the disclosure will be described in detail with reference to the accompanying drawings. In the following description, the singular forms “a,” “an,” and “the” are intended to include the plural forms as well, unless the context clearly indicates otherwise.

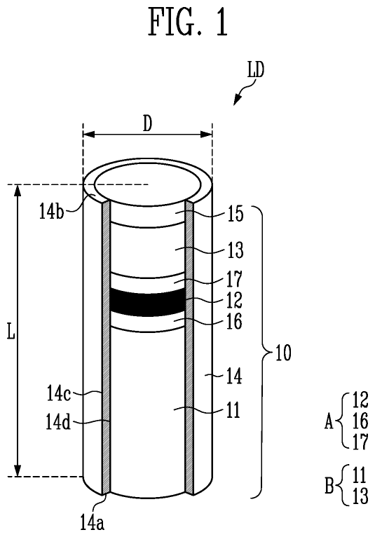

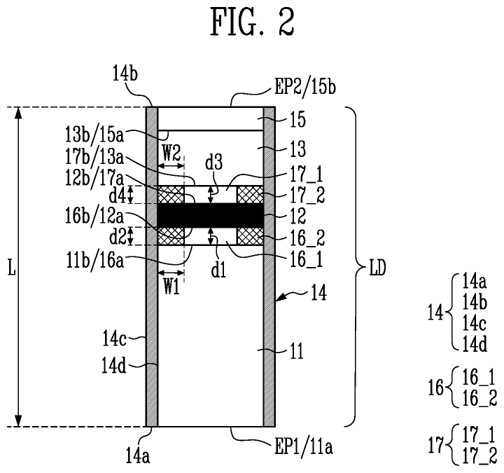

FIG. 1 is a schematic perspective view illustrating a light-emitting element according to an embodiment, and FIG. 2 is a schematic cross-sectional view of the light-emitting element of FIG. 1.

In an embodiment, the type and/or shape of the light-emitting element is not limited to an embodiment illustrated in FIGS. 1 and 2.

Referring to FIGS. 1 and 2, a light-emitting element LD may include a first semiconductor layer 11, a second semiconductor layer 13, and an active layer 12 interposed between the first semiconductor layer 11 and the second semiconductor layer 13. For example, the light-emitting element LD may further include an electrode or additional electrode 15 positioned or disposed on the second semiconductor layer 13.

In an embodiment, the light-emitting element LD may be implemented or formed as a light-emitting stack pattern 10 in which the first semiconductor layer 11, the active layer 12, and the second semiconductor layer 13 may be sequentially stacked.

The light-emitting element LD may be provided in a shape extending in one or in a direction. In a case that it is assumed that an extending direction of the light-emitting element LD is a direction of a length thereof, the light-emitting element LD may include a first end portion EP1 (or lower end portion) and a second end portion EP2 (or upper end portion) in the extending direction. One semiconductor layer of the first and second semiconductor layers 11 and 13 may be disposed at the first end portion EP1 (or lower end portion) of the light-emitting element LD, and the other semiconductor layer of the first and second semiconductor layers 11 and 13 may be disposed at the second end portion EP2 (or upper end portion) of the light-emitting element LD. In an embodiment, the first semiconductor layer 11 may be disposed at the first end portion EP1 (or lower end portion) of the light-emitting element LD, and the second semiconductor layer 13 may be disposed at the second end portion EP2 (or upper end portion) of the light-emitting element LD.

The light-emitting element LD may be provided or formed in various shapes. As an example, the light-emitting element LD may have a substantially rod-like shape, a substantially bar-like shape, or a substantially column shape which may be long in a direction of a length L (for example, may have an aspect ratio greater than one). In an embodiment, the length L of the light-emitting element LD in the direction of the length thereof may be greater than a diameter D (or width of a cross section) thereof. The light-emitting element LD may include, for example, a light-emitting diode (LED) manufactured in a very small size to such an extent as to have the diameter D and/or the length L ranging from a nanoscale to a microscale.

The diameter D of the light-emitting element LD may be in a range of about 0.5 μm to about 500 μm, and the length L thereof may be in a range of about 1 μm to about 10 μm. However, the diameter D and the length L of the light-emitting element LD are not limited thereto, and the size of the light-emitting element LD may be changed such that the light-emitting element LD meets requirements (or design conditions) of a lighting device or a self-luminous display device to which the light-emitting element LD may be applied.

As an example, the first semiconductor layer 11 may include at least one n-type semiconductor layer. For example, the first semiconductor layer 11 may be an n-type semiconductor layer which may include any one semiconductor material selected from InAlGaN, GaN, AlGaN, InGaN, AlN, and InN and may be doped with a first conductive type dopant (or n-type dopant) such as silicon (Si), germanium (Ge), tin (Sn), or tellurium (Te). However, the material constituting the first semiconductor layer 11 is not limited thereto, and the first semiconductor layer 11 may be made of various materials. In an embodiment, the first semiconductor layer 11 may include an aluminum gallium indium phosphorus (AlₓGa_{y}In_{z}P) semiconductor material doped with the first conductive dopant (or n-type dopant). The first semiconductor layer 11 may include an upper surface 11b positioned on the active layer 12 and a lower surface 11a externally exposed in the direction of the length L of the light-emitting element LD. The lower surface 11a of the first semiconductor layer 11 may be the first end portion EP1 (or lower end portion) of the light-emitting element LD.

The active layer 12 may be disposed on the first semiconductor layer 11 and may be formed to have a single or multi-quantum well structure. As an example, in a case that the active layer 12 is formed to have a multi-quantum well structure, in the active layer 12, a barrier layer (not illustrated), a strain reinforcing layer, and a well layer may be repeatedly and periodically stacked as one unit. The strain reinforcing layer may have a smaller lattice constant than the barrier layer to further reinforce strain, for example, compression stress applied to the well layer. However, the structure of the active layer 12 is not limited to the above-described embodiment.

The active layer 12 may emit light having a wavelength of in a range of about 400 nm to about 900 nm and may have a double hetero structure. In an embodiment, a clad layer (not illustrated) doped with a conductive dopant may be formed or disposed on an upper portion and/or a lower portion of the active layer 12 in the direction of the length L of the light-emitting element LD. As an example, the clad layer may be formed as an AlGaN layer or an InAlGaN layer. According to embodiments, a material such as AlGaN or InAlGaN may be used to form the active layer 12, and in addition, various materials may constitute the active layer 12. The active layer 12 may include a first surface 12a and a second surface 12b opposite to each other in the length L direction of the light-emitting element LD.

In a case that an electric field having a certain or predetermined voltage or more is applied to both end portions of the light-emitting element LD, electron-hole pairs combine, and thus, the light-emitting elements LD emit light. By controlling light emission of the light-emitting element LD using such a principle, the light-emitting element LD may be used as a light source (or light-emitting source) of various light-emitting devices including pixels of a display device.

The second semiconductor layer 13 may be disposed on the active layer 12 and may include a semiconductor layer which may be a different type from the first semiconductor layer 11. As an example, the second semiconductor layer 13 may include at least one p-type semiconductor layer. For example, the second semiconductor layer 13 may include a p-type semiconductor layer which may include at least one semiconductor material selected from InAlGaN, GaN, AlGaN, InGaN, AlN, and InN and may be doped with a second conductive type dopant (or p-type dopant) such as magnesium (Mg), zinc (Zn), calcium (Ca), strontium (Sr) or barium (Ba). However, the material constituting the second semiconductor layer 13 is not limited thereto, and the second semiconductor layer 13 may be made of various materials. In an embodiment, the second semiconductor layer 13 may include an aluminum gallium indium phosphorus (AlₓGa_{y}In_{z}P) semiconductor material doped with the second conductive dopant (or p-type dopant). The second semiconductor layer 13 may include a lower surface 13a positioned or disposed on the active layer 12 and an upper surface 13b in contact with the lower surface 15a of the additional electrode 15 in the direction of the length L of the light-emitting element LD.

In an embodiment, the first semiconductor layer 11 and the second semiconductor layer 13 may have different thicknesses in the length L direction of the light-emitting element LD. As an example, the first semiconductor layer 11 may have a thickness that may be relatively greater than that of the second semiconductor layer 13 in the length L direction of the light-emitting element LD. Accordingly, the active layer 12 of the light-emitting element LD may be positioned or disposed closer to the upper surface 13b of the second semiconductor layer 13 than the lower surface 11a of the first semiconductor layer 11.

Meanwhile, each of the first semiconductor layer 11 and the second semiconductor layer 13 are illustrated as being formed as one layer, but the disclosure is not limited thereto. In an embodiment, each of the first semiconductor layer 11 and the second semiconductor layer 13 may further include at least one layer, for example, a clad layer and/or a tensile strain barrier reducing (TSBR) layer according to a material of the active layer 12. The TSBR layer may be a strain reducing layer disposed between semiconductor layers having different lattice structures to serve as a buffer for reducing a lattice constant difference. The TSBR layer may be formed as a p-type semiconductor layer including p-GaInP, p-AlInP, or p-AlGaInP, but the disclosure is not limited thereto.

According to embodiments, the light-emitting stack pattern 10 may further include the additional electrode 15 disposed on the second semiconductor layer 13.

The additional electrode 15 may be in contact with the upper surface 13b of the second semiconductor layer 13. The additional electrode 15 may be an ohmic contact electrode electrically connected to the second semiconductor layer 13. The additional electrode 15 may include a conductive material having a transmittance (or light transmittance) of a certain or predetermined level or more. As an example, the additional electrode 15 may be made of one or a mixture or combination of chromium (Cr), titanium (Ti), aluminum (Al), gold (Au), nickel (Ni), indium tin oxide (ITO), indium zinc oxide (IZO), indium tin zinc oxide (ITZO), and an oxide or alloy thereof. The additional electrode 15 may be substantially transparent. Accordingly, light generated in the active layer 12 of the light-emitting element LD may pass through the additional electrode 15 to be externally emitted from the light-emitting element LD. The additional electrode 15 may include a lower surface 15a in contact with the second semiconductor layer 13 and an upper surface 15b externally exposed in the length L direction of the light-emitting element LD. In an embodiment, the upper surface 15b of the additional electrode 15 may be the second end portion EP2 (or upper end portion) of the light-emitting element LD.

In the above-described embodiment, the additional electrode 15 has been described and illustrated as a conductive layer formed as a single-film made of a transparent metal oxide and/or a single-film made of an opaque metal, but the disclosure is not limited thereto. According to embodiments, the additional electrode 15 may be formed as a multi-layer in which a conductive layer made of at least one transparent metal oxide and a conductive layer made of at least one opaque metal may be stacked.

In an embodiment, the light-emitting stack pattern 10 may further include a first barrier layer 16 and a second barrier layer 17. The second barrier layer 17 may be disposed on the first barrier layer 16 with the active layer 12 interposed therebetween in the length L direction of the light-emitting element LD. In an embodiment, the light-emitting stack pattern 10 may include an undoped region A and a doped region B. The undoped region A may include the first barrier layer 16, the active layer 12, and the second barrier layer 17, and the doped region B may include the first semiconductor layer 11 and the second semiconductor layer 13.

The first barrier layer 16 may be provided or disposed between the first semiconductor layer 11 and the active layer 12 and may be a semiconductor layer, for example, an intrinsic semiconductor layer. Here, the intrinsic semiconductor layer may be an undoped semiconductor layer or an unintentionally doped semiconductor layer. The unintentionally doped semiconductor layer may refer to a semiconductor layer which is not doped with a dopant, for example, an n-type dopant such as a silicon (Si) atom during a process of growing the semiconductor layer and in which an N-vacancy has occurred. In this case, in a case that the number of N-vacancies is increased, a concentration of surplus electrons is increased. Thus, it may be possible to unintentionally obtain electrical characteristics similar to those in the case of doping with an n-type dopant in a manufacturing process.

The first barrier layer 16 may be grown (or disposed) between the first semiconductor layer 11 and the active layer 12, thereby preventing the n-type dopant doped in the first semiconductor layer 11 from flowing to the active layer 12. For example, the first barrier layer 16 may prevent reverse flow of electrons from the active layer 12 to the first semiconductor layer 11. Due to a difference in band gap due to doping, the first barrier layer 16 may serve as a barrier to prevent the reverse flow of electrons from the active layer 12 to the first semiconductor layer 11, thereby contributing to an increase in internal quantum efficiency by increasing the possibility of a hole-electron combination in the active layer 12.

The first barrier layer 16 may be made of any one semiconductor material selected from AlInP including aluminum (Al), indium (In), and phosphorus (P) and AlGaAs including aluminum (Al), gallium (Ga), and arsenic (As). In an embodiment, the first barrier layer 16 may be formed as a semiconductor layer having a higher aluminum (Al) composition than the first and second semiconductor layers 11 and 13 included in the doped region B. The first barrier layer 16 may include a lower surface 16a in contact with the first semiconductor layer 11 and an upper surface 16b in contact with the active layer 12.

The second barrier layer 17 may be provided between the active layer 12 and the second semiconductor layer 13 and may be a semiconductor layer, for example, an intrinsic semiconductor layer. The second barrier layer 17 may include the same or similar material as the first barrier layer 16. As an example, the second barrier layer 17 may be made of any one semiconductor material selected from AlInP including aluminum (Al), indium (In), and phosphorus (P) and AlGaAs including aluminum (Al), gallium (Ga), and arsenic (As). However, the disclosure is not limited thereto, and according to embodiments, the second barrier layer 17 may include a material different from that of the first barrier layer 16. In an embodiment, the second barrier layer 17 may be formed as a semiconductor layer having a higher aluminum (Al) composition than the first and second semiconductor layers 11 and 13 included in the doped region B.

In an embodiment, the second barrier layer 17 may be grown (or disposed) between the active layer 12 and the second semiconductor layer 13, thereby preventing the p-type dopant doped in the second semiconductor layer 13 from flowing to the active layer 12. For example, the second barrier layer 17 may be grown (or disposed) between the active layer 12 and the second semiconductor layer 13, thereby preventing the reverse flow of holes from the active layer 12 to the second semiconductor layer 13. Due to a difference in band gap due to doping, the second barrier layer 17 may serve as a barrier to prevent the reverse flow of holes from the active layer 12 to the second semiconductor layer 13, thereby contributing to an increase in internal quantum efficiency by increasing the possibility of a hole-electron combination in the active layer 12. The second barrier layer 17 may include a lower surface 17a in contact with the active layer 12 and an upper surface 17b in contact with the second semiconductor layer 13.

In an embodiment, the light-emitting stack pattern 10 may be provided and/or formed and/or disposed to have a shape substantially corresponding to a shape of the light-emitting element LD. For example, in a case that the light-emitting element LD is provided and/or formed and/or disposed to have a substantially cylindrical shape, the light-emitting stack pattern 10 may also be provided and/or formed and/or disposed to have a substantially cylindrical shape. In a case that the light-emitting stack pattern 10 has a substantially cylindrical shape, each of the first semiconductor layer 11, the first barrier layer 16, the active layer 12, the second barrier layer 17, the second semiconductor layer 13, and the additional electrode 15 may have a substantially cylindrical shape.

In the length L direction of the light-emitting element LD, the first semiconductor layer 11 may be disposed at the first end portion EP1 (or lower end portion) of the light-emitting element LD, and the additional electrode 15 electrically connected to the second semiconductor layer 13 may be disposed at the second end portion EP2 (or upper end portion) of the light-emitting element LD. The light-emitting element LD may include the lower surface 11a of the first semiconductor layer 11 and the upper surface 15b of the additional electrode 15, which may be positioned or disposed at both end portions EP1 and EP2 of the light-emitting element LD and may be externally exposed. The lower surface 11a of the first semiconductor layer 11 and the upper surface 15b of the additional electrode 15 may be surfaces (for example, outer surfaces) which may be externally exposed to be in contact with external conductive materials, for example, contact electrodes and to be electrically connected to the contact electrodes.

In a case that the light-emitting stack pattern 10 is provided and/or formed and/or disposed to have the shape substantially corresponding to the shape of the light-emitting element LD, the light-emitting stack pattern 10 may have a length that may be substantially similar to or the same as the length L of the light-emitting element LD.

In an embodiment, the light-emitting element LD may further include an insulating film 14. However, according to embodiments, the insulating film 14 may be omitted and may also be provided to cover or overlap only a portion of the light-emitting stack pattern 10.

The insulating film 14 may prevent an electrical short circuit that may occur in a case that the active layer 12 contacts conductive materials other than the first and second semiconductor layers 11 and 13. For example, the insulating film 14 may minimize surface defects of the light-emitting element LD, thereby improving a lifespan and luminous efficiency of the light-emitting element LD. Furthermore, in a case that a plurality of light-emitting elements LD may be closely disposed, the insulating film 14 may prevent an undesired short circuit that may occur between the light-emitting elements LD. In a case that the active layer 12 may be prevented from being short-circuited with an external conductive material, whether the insulating film 14 may be provided is not limited.

The insulating film 14 may include a transparent insulating material. For example, the insulating film 14 may include at least one insulating material selected from the group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), magnesium oxide (MgO), zinc oxide (ZnO), ruthenium oxide (RuOx), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), an alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and vanadium nitride (VN). However, the disclosure is not limited thereto, and various materials having insulating properties may be used as the material of the insulating film 14.

The insulating film 14 may be provided in the form of a single-film or in the form of a multi-film including at least two films. As an example, in a case that the insulating film 14 is formed as a double-film including a first layer and a second layer which may be sequentially stacked, the first layer and the second layer may be made of different substances (or materials) and may be formed through different processes. According to embodiments, the first layer and the second layer may include the same or similar material.

The insulating film 14 may be formed and/or provided and/or disposed on an outer circumferential surface (or surface) of the light-emitting stack pattern 10 to at least surround the outer circumferential surface of the active layer 12. For example, the insulating film 14 may further surround an outer circumferential surface of each of the first semiconductor layer 11, the first barrier layer 16, the second barrier layer 17, the second semiconductor layer 13, and the additional electrode 15. For convenience of description, FIG. 1 illustrates a state in which a portion of the insulating film 14 is deleted or removed, and the first semiconductor layer 11, the first barrier layer 16, the active layer 12, the second barrier layer 17, the second semiconductor layer 13, and the additional electrode 15 included in the light-emitting element LD may be actually surrounded by the insulating film 14. In an embodiment, the insulating film 14 may completely surround each of the outer circumferential surface of the first semiconductor layer 11 and the outer circumferential surface of the additional electrode 15, but the disclosure is not limited thereto. According to embodiments, the insulating film 14 may surround only a portion of the outer circumferential surface of the first semiconductor layer 11 and/or only a portion of the circumferential surface of the additional electrode 15.

The insulating film 14 may include a lower surface 14a parallel to the lower surface 11a of the first semiconductor layer 11 in a direction intersecting the length L direction of the light-emitting element LD, an upper surface 14b opposite to the lower surface 14a in the length L direction, an inner side surface 14d that may be in direct contact with (or may touch) the light-emitting stack pattern 10, and an outer side surface 14c opposite to the inner side surface 14d and corresponding to an outermost side surface. The lower surface 14a of the insulating film 14, the upper surface 14b of the insulating film 14, the outer side surface 14c of the insulating film 14, and the inner side surface 14d of the insulating film 14 may be consecutively connected to each other. Here, the upper surface 14b of the insulating film 14 may be defined as a virtual surface including an upper circumference of the insulating film 14, and the lower surface 14a of the insulating film 14 may be defined as a virtual surface including a lower circumference of the insulating film 14.

The lower surface 14a of the insulating film 14 may be positioned or disposed on the same surface (or the same line) as the lower surface 11a of the first semiconductor layer 11, and the upper surface 14b of the insulating film may be positioned or disposed on the same surface (or the same line) as the upper surface 15b of the additional electrode 15. The lower surface 14a of the insulating film 14 and the lower surface 11a of the first semiconductor layer 11 do not necessarily have to be positioned or disposed on the same surface (or the same line) and may be positioned or disposed on different surfaces (or different lines) according to embodiments. Similarly, the upper surface 14b of the insulating film 14 and the upper surface 16b of the additional electrode 15 do not necessarily have to be positioned or disposed on the same surface (or the same line) and may be positioned or disposed on different surfaces (or different lines) according to embodiments.

The first semiconductor layer 11, the first barrier layer 16, the active layer 12, the second barrier layer 17, the second semiconductor layer 13, and the additional electrode 15, which may be sequentially stacked in the length L direction of the light-emitting element LD, may have different thicknesses, but the disclosure is not limited thereto.

The light-emitting element LD may be grown and manufactured on a substrate (not illustrated) for epitaxial growth.

Meanwhile, the first barrier layer 16 may be divided into or may include a first region 16_1 and a second region 16_2. As illustrated in FIG. 2, the first region 16_1 may be positioned or disposed in a central region of the first barrier layer 16, and the second region 16_2 may be positioned or disposed in the remaining region excluding the central region of the first barrier layer 16.

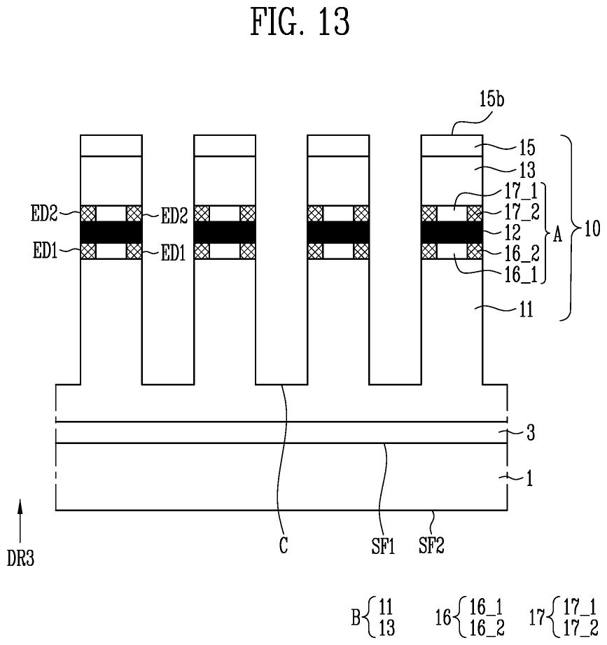

The first region 16_1 and the second region 16_2 may be classified according to whether oxygen is provided. For example, the first region 16_1 and the second region 16_2 may be classified according to whether an oxide layer, which is an oxidized region, is provided. The first region 16_1 may be one or a region of the first barrier layer 16 which may not include an oxide layer, and the second region 16_2 may be one or a region of the first barrier layer 16 which may include an oxide layer. The first region 16_1 may be an intrinsic semiconductor layer including one semiconductor material selected from AlInP and AlGaAs, and the second region 16_2 may include an oxide layer formed by combining the one semiconductor material with oxygen. The second region 16_2 may include an oxide layer formed by exposing, heat-treating, and oxidizing a first edge (see “ED1” of FIG. 13) (or edge portion) of the first barrier layer 16 in a process of manufacturing the light-emitting stack pattern 10. The above-described oxidation may be performed from the first edge ED1 (or edge portion) of the first barrier layer 16 to the inside (or center) thereof. The second region 16_2 including the oxide layer formed through the above-described oxidation may have relatively high resistance and a relatively low refractive index as compared with the first region 16_1 not including the oxide layer. In an embodiment, the second region 16_2 including the oxide layer may be used as an insulating layer.

The first region 16_1 and the second region 16_2 may have the same thickness in the length L direction of the light-emitting element LD. As an example, a thickness d1 of the first region 16_1 and a thickness d2 of the second region 16_2 may be the same or may be about the same. In an embodiment, a width W1 of the second region 16_2 may be different from a width of the first region 16_1 in a direction intersecting the length L direction of the light-emitting element LD. As an example, the width W1 of the second region 16_2 may be smaller than the width of the first region 16_1. In an embodiment, a thickness d1 of the first region 16_1 and a thickness d2 of the second region 16_2 may be about 500 nm or less. The width W1 of the second region 16_2 may be about 150 nm or less. However, the disclosure is not limited thereto, and the thickness d1 of the first region 16_1, the thickness d2 of the second region 16_2, and the width W1 of the second region 16_2 may be variously changed according to embodiments.

The second barrier layer 17 may be divided into or may include a third region 17_1 and a fourth region 17_2. As illustrated in FIG. 2, the third region 17_1 may be positioned or disposed in a central region of the second barrier layer 17, and the fourth region 17_2 may be positioned or disposed in the remaining region excluding the central region of the second barrier layer 17.

The third region 17_1 and the fourth region 17_2 may be classified according to whether oxygen is provided. For example, the third region 17_1 and the fourth region 17_2 may be classified according to whether an oxide layer, which is an oxidized region, is provided. The third region 17_1 may be one or a region of the second barrier layer 17 which may not include an oxide layer, and the fourth region 17_2 may be one or a region of the second barrier layer 17 which may include an oxide layer. The third region 17_1 may be an intrinsic semiconductor layer including one semiconductor material selected from AlInP and AlGaAs, and the fourth region 17_2 may include an oxide layer formed by combining the one semiconductor material with oxygen. The fourth region 17_2 may include an oxide layer formed by exposing, heat-treating, and oxidizing a second edge (see “ED2” of FIG. 13) (or second edge portion) of the second barrier layer 17 in a process of manufacturing the light-emitting stack pattern 10. The above-described oxidation may be performed from the second edge ED2 (or edge portion) of the second barrier layer 17 to the inside (or center) thereof. The fourth region 17_2 formed through the above-described oxidation may have relatively high resistance and a relatively low refractive index as compared with the third region 17_1 not including the oxide layer. In an embodiment, the fourth region 17_2 including the oxide layer may be used as an insulating layer.

The third region 17_1 and the fourth region 17_2 may have the same thickness in the length L direction of the light-emitting element LD. As an example, a thickness d3 of the third region 17_1 and a thickness d4 of the fourth region 17_2 may be the same or may be about the same. In an embodiment, a width W2 of the fourth region 17_2 may be smaller than a width of the third region 17_1 in the direction intersecting the length L direction of the light-emitting element LD. In an embodiment, the thickness d3 of the third region 17_1 and the thickness d4 of the fourth region 17_2 may be about 500 nm or less. The width W2 of the fourth region 17_2 may be about 150 nm or less. However, the disclosure is not limited thereto, and the thickness d3 of the third region 17_1, the thickness d4 of the fourth region 17_2, and the width W2 of the fourth region 17_2 may be variously changed according to embodiments.

In an embodiment, the thickness d2 of the second region 16_2 of the first barrier layer 16 and the thickness d4 of the fourth region 17_2 of the second barrier layer 17 may be the same or about the same in the length L direction of the light-emitting element LD. However, the disclosure is not limited thereto, and the thickness d2 of the second region 16_2 of the first barrier layer 16 and the thickness d4 of the fourth region 17_2 of the second barrier layer 17 may be different according to embodiments.

As described above, in a case that the first barrier layer 16 including the oxide layer is disposed between the first semiconductor layer 11 and the active layer 12, and the second barrier layer 17 including the oxide layer is disposed between the active layer 12 and the semiconductor layers 13, in a process of manufacturing the light-emitting stack pattern 10 through an etching method, a surface leakage current due to surface damage of the undoped region A may be blocked, thereby improving luminous efficiency of the light-emitting element LD.

By way of example, in a case that heat treatment or the like is performed on a surface of the light-emitting stack pattern 10 etched in a vertical direction through a dry etching method or the like, an oxide layer, which may be an insulating region having a very high resistance component, may be formed in a portion of the first barrier layer 16 and a portion of the second barrier layer 17. The oxide layer may be included in each of the second region 16_2 of the first barrier layer 16 and the fourth region 17_2 of the second barrier layer 17.

In a related art light-emitting element that may not include an oxide layer, during a dry etching process for forming the light-emitting stack pattern 10, a surface of the undoped region A of the light-emitting stack pattern 10 may be exposed and thus damaged by an etching gas used in the dry etching process. In this case, in the related art light-emitting element, in a process of injecting a current for operating, a significant surface leakage current may be generated, resulting in decrease in luminous efficiency of the light-emitting element.

As in an embodiment, in a case that the first barrier layer 16 including the oxide layer is disposed between the first semiconductor layer 11 and the active layer 12, and the second barrier layer 17 including the oxide layer is disposed between the active layer 12 and the second semiconductor layer 13, surface resistance in the undoped region A of the light-emitting stack pattern 10 may be relatively increased. Surface resistance of the second region 16_2 of the first barrier layer 16 and the fourth region 17_2 of the second barrier layer 17, which may be in contact with the inner side surface 14d of the insulating film 14 in the undoped region A, may be relatively increased. Accordingly, a leakage current path on the surface of the light-emitting stack pattern 10 (or light-emitting element LD) may be blocked to reduce a surface leakage current, thereby improving luminous efficiency of the light-emitting element LD.

The light-emitting element LD may be used as a light source (or light-emitting source) of various display devices. The light-emitting element LD may be manufactured through a surface treatment process. For example, in a case that a plurality of light-emitting elements LD may be mixed in a flowable solution (or solvent) and supplied to each pixel area (for example, an emission area of each pixel or an emission area of each subpixel), the light-emitting elements LD may be surface-treated so as to be uniformly sprayed without being non-uniformly aggregated in the solution.

A light-emitting unit (or light-emitting device) including the light-emitting element LD may be used in various types of electronic devices, such as display devices, which require a light source. For example, in a case that the plurality of light-emitting elements LD are disposed in a pixel area of each pixel of a display panel, the light-emitting elements LD may be used as light sources for each pixel. However, the application field of the light-emitting element LD is not limited to the above-described example. For example, the light-emitting element LD may be used in other types of electronic devices, such as lighting devices, which require a light source.

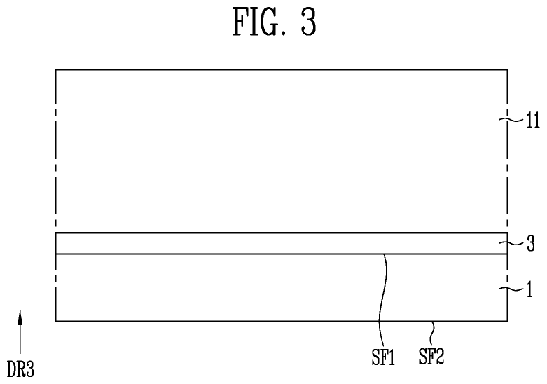

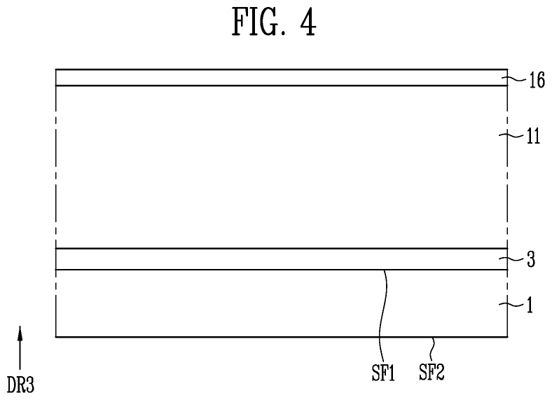

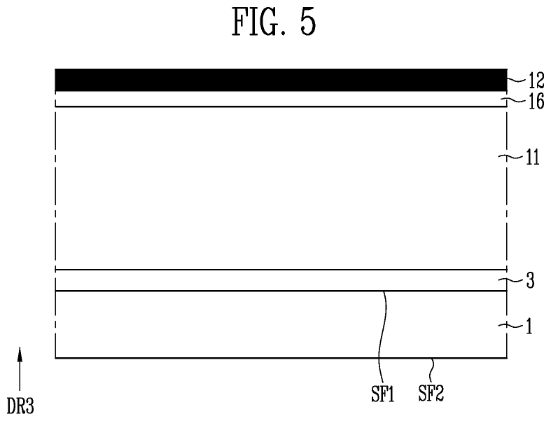

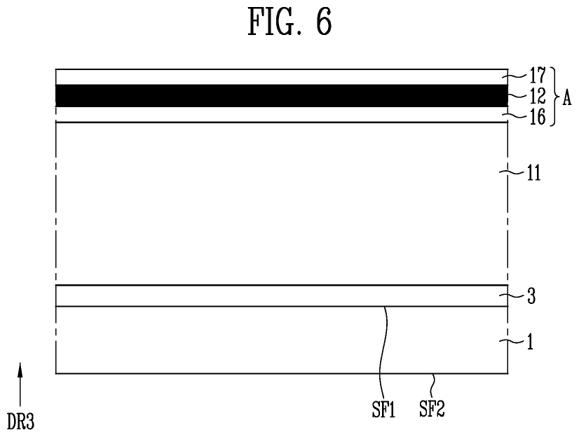

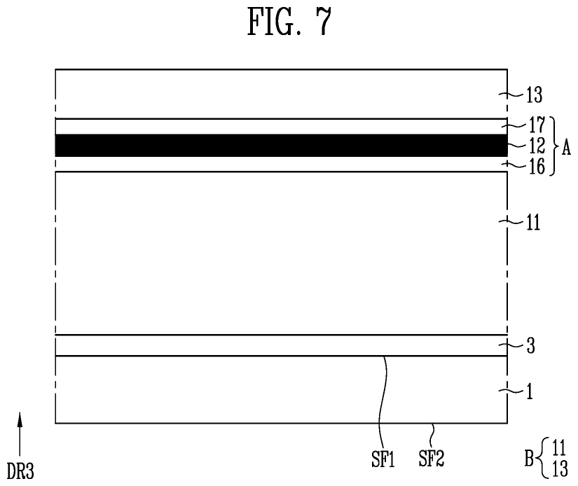

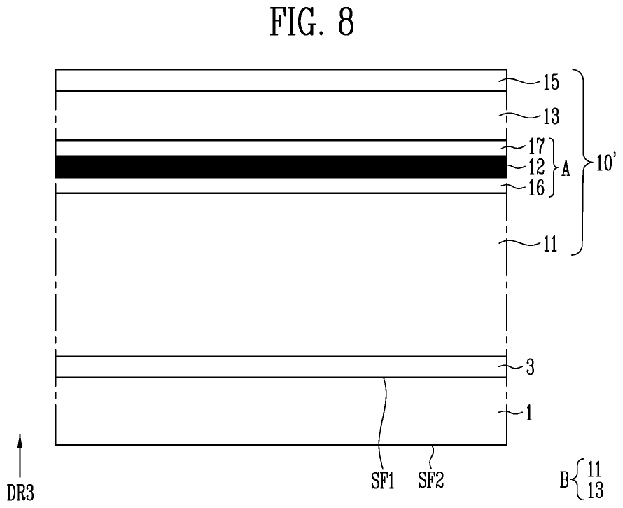

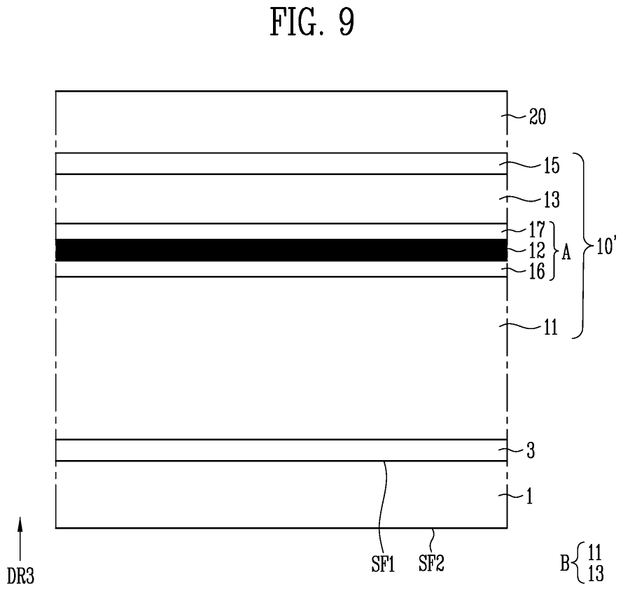

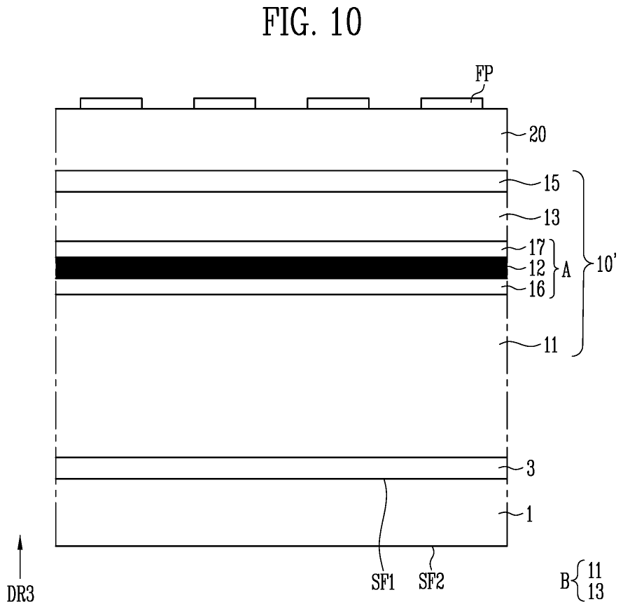

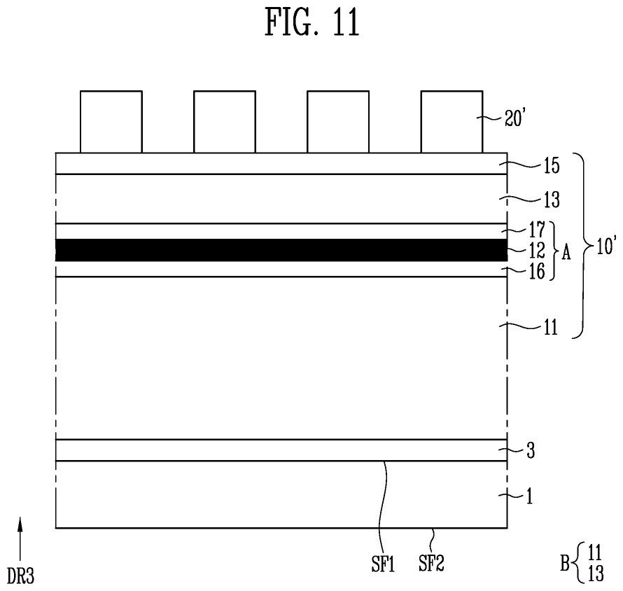

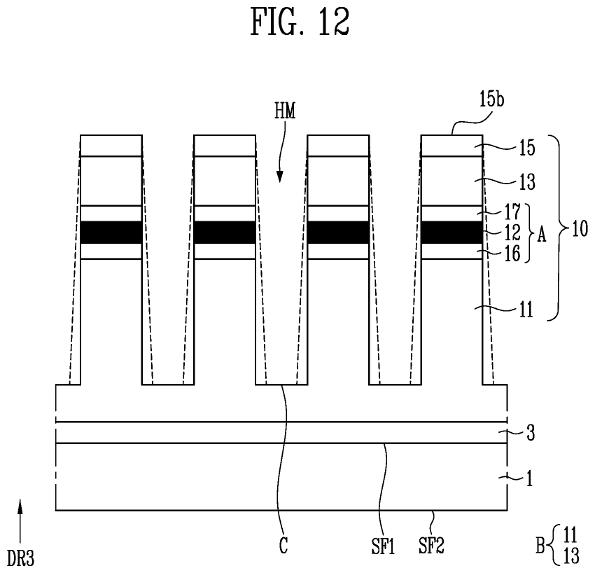

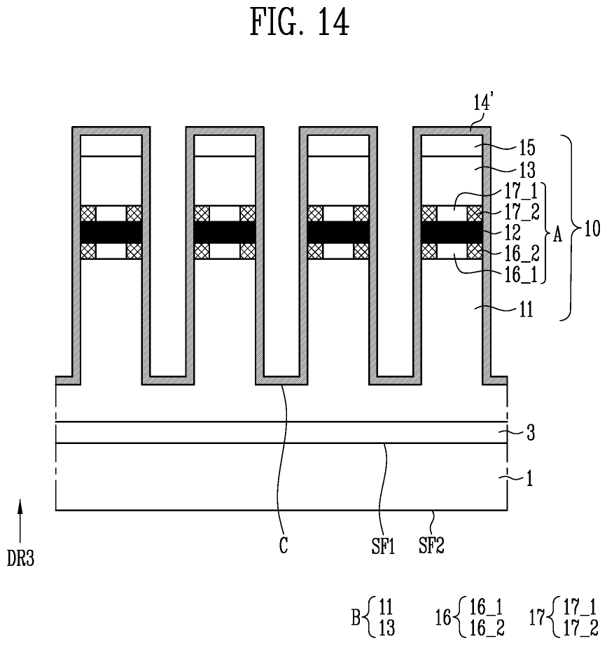

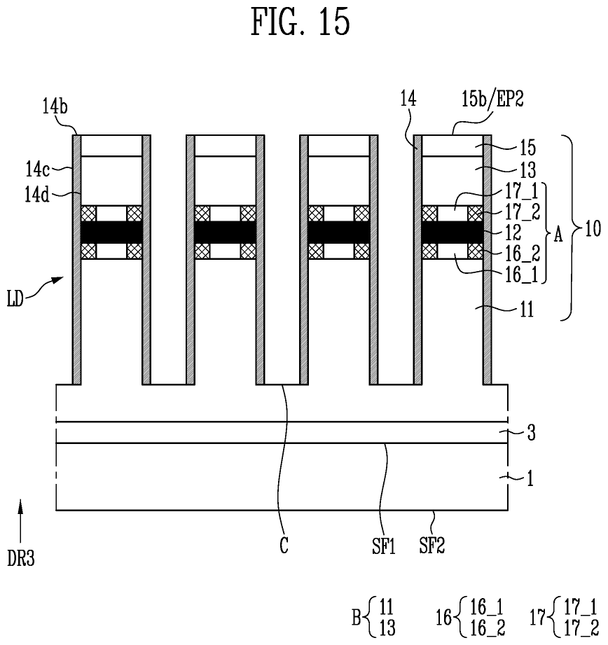

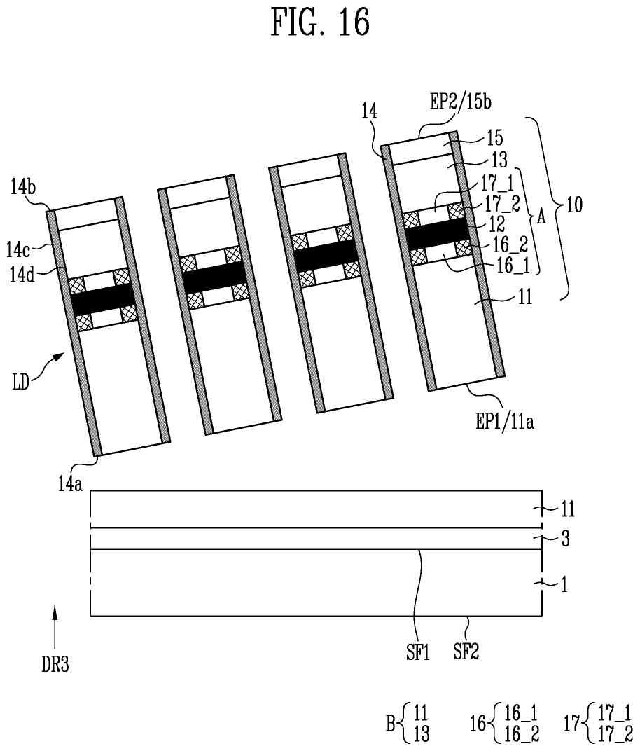

FIGS. 3 to 16 are schematic cross-sectional views sequentially illustrating a method of manufacturing the light-emitting element of FIGS. 1 and 2.

Referring to FIGS. 1 to 3, a substrate 1 to support a light-emitting element LD may be provided.

The substrate 1 may be a GaAs, GaP, or InP substrate. The substrate 1 may be a wafer (or growth substrate) for epitaxial growth. The substrate 1 may include a ZnO substrate including a GaAs layer on a surface thereof. Furthermore, a Ge substrate including a GaAs layer on a surface thereof and a Si substrate including a GaAs layer on a Si wafer with a buffer layer interposed therebetween may also be applied.

As for the substrate 1, a commercially available single crystal substrate manufactured through a manufacturing method may be used. In a case that selectivity for manufacturing the light-emitting element LD is satisfied and epitaxial growth is smoothly performed, the material of the substrate 1 is not limited thereto.

A surface of the substrate 1, upon which epitaxial growth is to be performed, may be flat. The size and diameter of the substrate 1 may vary according to a product to which the substrate 1 may be applied, and the substrate 1 may be manufactured in a form capable of reducing a warpage caused by a stacked structure due to epitaxial growth. The shape of the substrate 1 is not limited to a substantially circular shape but may be a substantially polygonal shape such as a substantially rectangular shape.

A sacrificial layer 3 may be formed on a first surface SF1 (or upper surface) of the substrate 1. In a process of manufacturing the light-emitting element LD, the sacrificial layer 3 may be positioned or disposed between the light-emitting element LD and the substrate 1 to physically separate the light-emitting element LD and the substrate 1. In this case, as illustrated in FIG. 3, a second surface SF2 (or rear surface) opposite to the first surface SF1 of the substrate 1 may face downward in a thickness direction DR3 of the substrate 1 (hereinafter, referred to as a “third direction”).

The sacrificial layer 3 may have various types of structures and may have a single-layered structure or a multi-layered structure. The sacrificial layer 3 may be a layer that may be removed in a final manufacturing process of the light-emitting element LD. In a case that the sacrificial layer 3 is removed, layers positioned or disposed on and below the sacrificial layer 3 may be separated. The sacrificial layer 3 may be made of GaAs, AlAs, or AlGaAs.

A first semiconductor layer 11 may be formed on the sacrificial layer 3. The first semiconductor layer 11 may be formed through epitaxial growth and formed through a metal-organic chemical vapor deposition (MOCVD) method, a molecular beam epitaxy (MBE) method, a vapor phase epitaxy (VPE) method, a liquid phase epitaxy (LPE) method, or the like within the spirit and the scope of the disclosure. According to embodiments, a buffer layer or an additional semiconductor layer such as an undoped semiconductor layer for improving crystallinity may be further formed or disposed between the first semiconductor layer 11 and the sacrificial layer 3.

The first semiconductor layer 11 may include a group III (Ga, Al, or In)—V (P or As) semiconductor material and may include a semiconductor layer doped with a first conductive type dopant (n-type dopant) such as Si, Ge, Sn, or Te. For example, the first semiconductor layer 11 may include at least one semiconductor material selected from GaP, GaAs, GaInP, and AlGaInP doped with Si. For example, the first semiconductor layer 11 may include at least one n-type semiconductor layer.

Referring to FIGS. 1 to 4, a first barrier layer 16 may be formed on the first semiconductor layer 11.

The first barrier layer 16 may be an intrinsic semiconductor layer (or undoped semiconductor layer) made of any one semiconductor material selected from AlInP and AlGaAs. In an embodiment, the first barrier layer 16 may be formed as a semiconductor layer having a higher aluminum (Al) composition than the first semiconductor layer 11. In a case that the first barrier layer 16 is formed as the semiconductor layer having a higher aluminum (Al) composition than the first semiconductor layer 11, the first barrier layer 16 may be more rapidly combined with oxygen in a heat treatment process to be described below as compared with the first semiconductor layer 11, which may make it possible to form an oxide layer having high resistance.

The first barrier 16 may be formed through epitaxial growth and formed through an MOCVD method, an MBE method, a VPE method, an LPE method, or the like within the spirit and the scope of the disclosure.

Referring to FIGS. 1 to 5, an active layer 12 may be formed or disposed on the first barrier layer 16. The active layer 12 may be a region in which electrons and holes are recombined. As electrons and holes are recombined to transition to a low energy level, the active layer 12 may emit light having a wavelength corresponding thereto. The active layer 12 may be formed or disposed on the first barrier layer 16 and may be formed to have a single or multi-quantum well structure. The position of the active layer 12 may be variously changed according to the size or the like of the light-emitting element LD.

The active layer 12 may include at least one material selected from GaInP, AlGaInP, GaAs, AlGaAs, InGaAs, InGaAsP, InP, and InAs. The active layer 12 may emit light having a wavelength in a range of about 400 nm to about 900 nm. The active layer 12 may have a double hetero structure. According to embodiments, a cladding layer (not illustrated) doped with a conductive dopant may be further formed or disposed on a first surface 12a and/or a second surface 12b of the active layer 12. According to an embodiment, a TSBR layer may be further formed or disposed on the first surface 12a of the active layer 12.

Referring to FIGS. 1 to 6, a second barrier layer 17 may be formed or disposed on the active layer 12.

The second barrier layer 17 may be an intrinsic semiconductor layer (or undoped semiconductor layer) made of any one semiconductor material selected from AlInP and AlGaAs. According to embodiments, the second barrier layer 17 may include the same or similar material as the first barrier layer 16. In an embodiment, the second barrier layer 17 may be formed as a semiconductor layer having a higher aluminum (Al) composition than first and second semiconductor layers 11 and 13. In a case that the second barrier layer 17 is formed as the semiconductor layer having a higher aluminum (Al) composition than the first and second semiconductor layers 11 and 13, the second barrier layer 17 may be more rapidly combined with oxygen in a heat treatment process to be described below as compared with the first and second semiconductor layers 11 and 13, which may make it possible to form an oxide layer having high resistance. In this case, the second barrier layer 17 may be formed as a semiconductor layer having the same aluminum (Al) composition as the first barrier layer 16, but the disclosure is not limited thereto. According to embodiments, the second barrier layer 17 may be formed as a semiconductor layer having a higher aluminum (Al) composition than the first barrier layer 16.

The second barrier layer 17 may be formed through epitaxial growth and formed through an MOCVD method, an MBE method, a VPE method, an LPE method, or the like within the spirit and the scope of the disclosure.

The first barrier layer 16, the active layer 12, and the second barrier layer 17 sequentially stacked in a third direction DR3 may be included in an undoped region A of a light-emitting stack pattern 10 (or light-emitting element LD).

Referring to FIGS. 1 to 7, the second semiconductor layer 13 may be formed on the second barrier layer 17. The second semiconductor layer 13 may include a semiconductor layer which may be a different type from the first semiconductor layer 11. The second semiconductor layer 13 may include a group III (Ga, Al, or In)—V (P or As) semiconductor material and may include a semiconductor layer doped with a second conductive type dopant (or p-type dopant) such as magnesium Mg, zinc Zn, calcium Ca, strontium Sr, or barium Ba. For example, the second semiconductor layer 13 may include at least one semiconductor material selected from GaP, GaAs, GaInP, and AlGaInP doped with Mg. For example, the second semiconductor layer 13 may include a p-type semiconductor layer.

In an embodiment, the first and second semiconductor layers 11 and 13 may be included in a doped region B of the light-emitting stack pattern 10 (or light-emitting element LD).

Referring to FIGS. 1 to 8, an additional electrode 15 may be formed or disposed on the second semiconductor layer 13. The additional electrode 15 may be made of one or a mixture of chromium (Cr), titanium (Ti), aluminum (Al), gold (Au), nickel (Ni), indium tin oxide (ITO), indium zinc oxide (IZO), indium tin zinc oxide (ITZO), and an oxide or alloy thereof. In an embodiment, in order to minimize a loss of light generated in the active layer 12 and externally emitted from the light-emitting element LD and improve current spreading to the second semiconductor layer 13, the additional electrode 15 may be made of a transparent conductive oxide such as indium tin oxide (ITO).

The additional electrode 15 may be an ohmic contact electrode. As an example, the additional electrode 15 may be in ohmic contact with the second semiconductor layer 13. However, the disclosure is not limited thereto, and according to embodiments, the additional electrode 15 may be a Schottky contact electrode.

The additional electrode 15 may be deposited on the second semiconductor layer 13 through a sputtering method. However, a method of forming the additional electrode 15 on the second semiconductor layer 13 is not limited to the above-described embodiment, and various deposition methods or the like may be applied. In consideration of an oxygen amount, a deposition temperature, and/or a deposition time in a chamber in which a deposition process is performed in a case that a corresponding electrode is formed, the thickness of the additional electrode 15 may be determined within a range in which a loss of light emitted from the active layer 12 may be minimized.

The first semiconductor layer 11, the first barrier layer 16, the active layer 12, the second barrier layer 17, the second semiconductor layer 13, and the additional electrode 15, which may be sequentially stacked on the sacrificial layer 3, may constitute a light-emitting stack 10′.

Referring to FIGS. 1 to 9, a mask layer 20 may be formed or disposed on the additional electrode 15. The mask layer 20 may include an insulating layer (not illustrated) and a metal layer (not illustrated). The insulating layer may be formed or disposed on the additional electrode 15. The insulating layer may serve as a mask for continuously etching the light-emitting stack 10′. The insulating layer may be made of an oxide or a nitride and may include, for example, silicon oxide (SiOₓ), silicon nitride (SiNₓ), or the like within the spirit and the scope of the disclosure. The metal layer may include a metal such as chromium (Cr), but the disclosure is not limited thereto.

Referring to FIGS. 1 to 10, one or more fine patterns FP may be formed on the mask layer 20. The fine pattern FP may be formed through a polymer layer. The fine patterns FP may be formed by forming the polymer layer on the mask layer 20 and forming patterns on the polymer layer at nanoscale to microscale intervals. By way of example, the polymer layer on the mask layer 20 may be patterned through a method such as a photo-lithography method, an electron beam lithography method, or a nanoimprint lithography (NIL) method, thereby forming the fine patterns FP at nanoscale to microscale intervals.

Referring to FIGS. 1 to 11, the mask layer 20 may be patterned using the fine patterns FP as a mask to form mask patterns 20′. The mask pattern 20′ may be formed to have a shape substantially corresponding to the fine pattern FP. The above-described mask pattern 20′ may be used as an etching mask for forming the light-emitting stack patterns 10 by etching the light-emitting stack 10′. The fine pattern FP may be removed through a typical wet etching method or dry etching method, but the disclosure is not limited thereto. The fine pattern FP may be removed through a typical removal method.

Referring to FIGS. 1 to 12, an etching process using the mask patterns 20′ as an etching mask may be performed to etch the light-emitting stack 10′ in a vertical direction, for example, in the third direction DR3 at nanoscale to microscale intervals, thereby forming the light-emitting stack patterns 10.

In the above-described etching process, one region of the light-emitting stack 10′, which may not correspond to the mask pattern 20′, may be etched to form a groove HM externally exposing one or a region C of the first semiconductor layer 11. One or a region of the light-emitting stack 10′, which may correspond to the mask pattern 20′, may not be etched.

The groove HM may have a shape that may be recessed from an upper surface 15b of the additional electrode 15 of each light-emitting stack pattern 10 to one or a region A of the first semiconductor layer 11 in the third direction DR3.

A dry etching method such as a reactive ion etching (RIE) method, a reactive ion beam etching (RIBE) method, or an inductively coupled plasma reactive ion etching (ICP-RIE) method may be used as an etching method of forming a plurality of light-emitting stack patterns 10. Different from that of a wet etching method, the dry etching method allows one-directional etching and thus is suitable for forming the light-emitting stack patterns 10. In the wet etching method, isotropic etching is performed, and thus, etching is performed in all directions. However, different from that of the wet etching method, in the dry etching method, etching may be mainly performed in a depth direction to form the groove HM so that the groove HM may have a size, a distance, or the like to be formed in a desired pattern. According to embodiments, the etching for the light-emitting stack patterns 10 may be performed by a combination of dry etching and wet etching. For example, after etching is performed in a depth direction through dry etching, an etched sidewall may be placed on a planar surface perpendicular to a surface through wet etching which is isotropic etching.

In an embodiment, each of the light-emitting stack patterns 10 may have a size ranging from a nanoscale to a microscale.

After the above-described etching process is performed, residues remaining on the light-emitting stack patterns 10, for example, the mask patterns 20′, may be removed through a wet etching or dry etching method, but the disclosure is not limited thereto. As an example, the mask pattern 20′ may be removed through a removal method.

Referring to FIGS. 1 to 13, the light emitting stack patterns 10, of which surfaces may be exposed after the above-described etching process, may be surface-treated through a heat treatment method, thereby forming oxide layers in the first and second barrier layers 16 and 17 (for example, a second region 16_2 of the first barrier layer 16 and a fourth region 17_2 of the second barrier layer 17).

For example, after the light-emitting stack patterns 10 with the exposed surfaces are formed, in a case that heat treatment is performed at a high temperature in an oxygen atmosphere, a partial surface of each of the light-emitting stack patterns 10 may be oxidized. At least a portion of each of the first and second barrier layers 16 and 17 having a relatively higher aluminum (Al) than the first and second semiconductor layers 11 and 13 may be oxidized to form an oxide layer. For example, a first edge ED1 with an exposed surface of the first barrier layer 16 and a second edge ED2 with an exposed surface of the second barrier layer 17 may be oxidized to form oxide layers.

The oxidation of the first barrier layer 16 may gradually proceed from the first edge ED1 with the exposed surface (or edge portion) to the inside (or center) thereof. The oxidation of the second barrier layer 17 may gradually proceed from the second edge ED2 with the exposed surface (or edge portion) to the inside (or center) thereof.

Each of the first and second barrier layers 16 and 17 may be divided into or may include a region including an oxide layer and a region not including an oxide layer through the above-described heat treatment method. For example, through the heat treatment method, the first barrier layer 16 may be divided into or may include a first region 16_1 that may be a region not including an oxide layer and the second region 16_2 that may be a region including an oxide layer. Through the heat treatment method, the second barrier layer 17 may be divided into or may include a third region 17_1 that may be a region not including an oxide layer and the fourth region 17_2 that may be a region including an oxide layer.

The first region 16_1 of the first barrier layer 16 may serve as a barrier to prevent the reverse flow of electrons from the active layer 12 to the first semiconductor layer 11, and the second region 16_2 of the first barrier layer 16 may have high resistance to serve as an insulating layer, thereby blocking a surface leakage current. The third region 17_1 of the second barrier layer 17 may serve as a barrier to prevent the reverse flow of holes from the active layer 12 to the second semiconductor layer 13, and the fourth region 17_2 of the second barrier layer 17 may have high resistance to serve as an insulating layer, thereby blocking a surface leakage current.

An oxidation degree of each of the first and second barrier layers 16 and 17 may be controlled in consideration of various conditions such as a composition of a semiconductor compound included in the corresponding barrier layer, an orientation of the compound, a thickness of a layer, and an oxidation process.

In the above-described embodiment, it has been described that one or a region of each of the first and second barrier layers 16 and 17 may be oxidized using a heat treatment method, but the disclosure is not limited thereto. According to embodiments, one or a region of each of the first and second barrier layers 16 and 17 may be oxidized using a wet etching process or the like within the spirit and the scope of the disclosure.

Referring to FIGS. 1 to 14, an insulating material layer 14′ may be formed on the light-emitting stack patterns 10 and the region C of the first semiconductor layer 11.

The insulating material layer 14′ may include an upper insulating material layer, a side insulating material layer, and a lower insulating material layer. The upper insulating material layer may completely cover or overlap an upper surface of each of the light-emitting stack patterns 10. Here, the upper surface of each of the light-emitting stack patterns 10 may be the upper surface 15b of the additional electrode 15. For example, the upper insulating material layer may completely cover or overlap the upper surface 15b of the additional electrode 15 of each of the light-emitting stack patterns 10. The side insulating material layer may completely cover or overlap a side surface of each of the light-emitting stack patterns 10. The lower insulating material layer may completely cover or overlap one or a region A of the first semiconductor layer 11 externally exposed by the groove HM.

The upper insulating material layer, the side insulating material layer, and the lower insulating material layer may be consecutively connected to each other on the light-emitting stack patterns 10.

As a method of forming the insulating material layer 14′, a method of applying an insulating material on the light-emitting stack patterns 10 positioned or disposed on the substrate 1, but the disclosure is not limited thereto. The insulating material layer 14′ may include a transparent insulating material. The insulating material layer 14′ may include at least one insulating material selected from the group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), an alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN)), and vanadium nitride (VN).

As an example, in a case that the insulating material layer 14′ may include aluminum oxide (AlOₓ), the insulating material layer 14′ may be formed through an atomic layer deposition (ALD) method. Trimethyl aluminum (TMA) and a H₂O source may be supplied in a pulse form to form a thin film using chemical adsorption and desorption. The insulating material layer 14′ may have a thickness in a range of about 30 nm to about 150 nm, but the disclosure is not limited thereto.

Referring to FIGS. 1 to 15, an etching process is performed to remove a portion of the insulating material layer 14′, thereby forming an insulating film 14. The above-described etching process may be a dry etching method.

Through the above-described etching process, the upper insulating material layer and the lower insulating material layer may be removed, and thus, the insulating film 14 including only the side insulating material layer covering or overlapping the side surface of each of the light-emitting stack patterns 10 may be finally formed. Through the above-described etching process, the upper insulating material layer may be removed to externally expose an upper surface 15b of the additional electrode 15. In this case, an upper surface 14b of the insulating film 14 may be provided and/or formed and/or disposed on the same surface (or the same line) as the upper surface 15b of the additional electrode 15. For example, through the above-described etching process, the lower insulating material layer may be removed to expose one or a region C of the first semiconductor layer 11.

Through the above-described etching process, a plurality of light-emitting elements LD including the light-emitting stack patterns 10 and the insulating film 14 surrounding an outer circumferential (or surface) of each of the light-emitting stack patterns 10 may be finally formed. In this case, the externally exposed upper surface 15b of the additional electrode 15 may be a second end portion EP2 (or upper surface) of each of the light-emitting elements LD.

Referring to FIGS. 1 to 16, an empty space (not illustrated) may be formed between the light-emitting elements LD and the substrate 1 to separate the light-emitting elements LD from the substrate 1 using a physical separation method in which a small physical force or impact may be applied. In this case, a lower surface 11a of the first semiconductor layer 11 of each of the light-emitting elements LD may be externally exposed. The externally exposed lower surface 11a of the first semiconductor layer 11 may be a first end portion EP1 (or lower end portion) of the light-emitting element LD.

A method of separating the light-emitting elements LD from the substrate 1 is not limited to the above-described embodiment. According to embodiments, the light-emitting elements LD may be separated from the substrate 1 through a laser lift-off (LLO) method using a laser, a chemical lift-off (CLO) method using an etching solution, or the like within the spirit and the scope of the disclosure.

Each of the light-emitting elements LD finally manufactured through the above-described manufacturing process may include the first and second barrier layers 16 and 17 including the oxide layers (for example, the second region 16_2 and the fourth region 17_2). Accordingly, a leakage current path on the surface of the light-emitting stack pattern 10 (or light-emitting element LD) may be blocked by the oxide layer to reduce a surface leakage current, thereby improving luminous efficiency of each of the light-emitting elements LD.

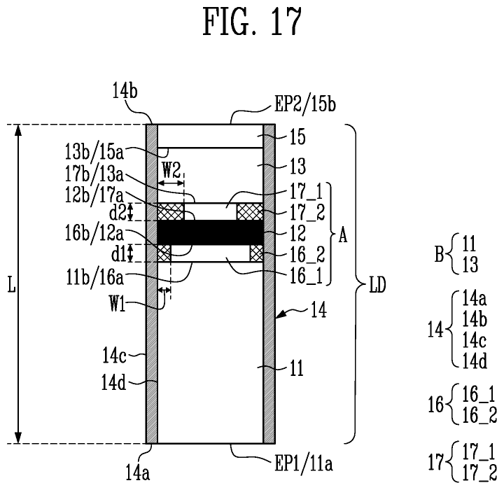

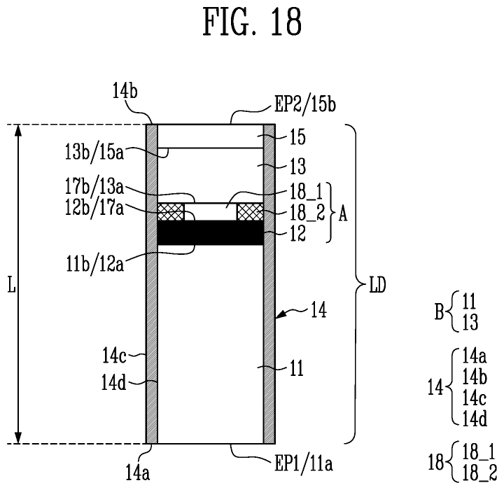

FIGS. 17 and 18 are schematic perspective views illustrating light-emitting elements according to embodiments.

A light-emitting element LD illustrated in FIG. 17 may have substantially the same or similar configuration as the light-emitting element LD of FIGS. 1 and 2 except that a width W2 of a fourth region 17_2 of a second barrier layer 17 and a width W1 of a second region 16_2 of a first barrier layer 16 may be different.

For example, a light-emitting element LD illustrated in FIG. 18 may have substantially the same or similar configuration as the light-emitting element LD of FIGS. 1 and 2 except that a first barrier layer 16 may be omitted.

Accordingly, in relation to the light-emitting elements of FIGS. 17 and 18, differences from the above-described embodiment will be mainly described in order to avoid redundant descriptions.

First, referring to FIG. 17, the light-emitting element LD according to an embodiment may include a light-emitting stack pattern 10 and an insulating film 14 surrounding a surface (or outer circumferential surface) of the light-emitting stack pattern 10.

The light-emitting stack pattern 10 may include a first semiconductor layer 11, the first barrier layer 16, an active layer 12, the second barrier layer 17, a second semiconductor layer 13, and an additional electrode 15 sequentially stacked in a length L direction of the light-emitting element LD. Here, the first barrier layer 16, the active layer 12, and the second barrier layer 17 may be included in an undoped region A of the light-emitting stack pattern 10. The first and second semiconductor layers 11 and 13 may be included in a doped region B of the light-emitting stack pattern 10.

The first barrier layer 16 may be divided into or may include the second region 16_2 including an oxide layer formed by oxidizing a portion of a surface during a manufacturing process and a first region 16_1 not including the oxide layer. The second barrier layer 17 may be divided into or may include the fourth region 17_2 including an oxide layer formed by oxidizing a portion of a surface during a manufacturing process and a third region 17_1 not including the oxide layer.

In an embodiment, each of the first and second barrier layers 16 and 17 may be made of any one semiconductor material selected from AlInP and AlGaAs. In this case, the first and second barrier layers 16 and 17 may be made of a semiconductor material having a higher aluminum (Al) composition than the first and second semiconductor layers 11 and 13. In an embodiment, the second barrier layer 17 may be made of a semiconductor material having a higher aluminum (Al) composition than the first barrier layer 16. Accordingly, in a case that the heat treatment method described with reference to FIG. 13 is performed, an oxidation rate of the second barrier layer 17 may be faster than that of the first barrier layer 16. In this case, an oxidation degree of the first barrier layer 16 and an oxidation degree of the second barrier layer 17 may be different. As an example, the second barrier layer 17 may have a higher oxidation reaction than the first barrier layer 16 so that the width W2 of the fourth region 17_2 including the oxide layer may be greater than the width W1 of the second region 16_2 including the oxide layer.

As in an embodiment, in a case that the light-emitting element LD may include the first barrier layer 16 including the second region 16_2 formed as the oxide layer and the second barrier layer 17 including the fourth region 17_2 formed as the oxide layer wider than the second region 16_2, surface resistance in the undoped region A of the light-emitting stack pattern 10 may be relatively increased. Accordingly, a leakage current path on the surface of the light-emitting stack pattern 10 (or light-emitting element LD) may be blocked to minimize a surface leakage current, thereby improving luminous efficiency of the light-emitting element LD.

Next, referring to FIG. 18, the light-emitting element LD according to an embodiment may include a light-emitting stack pattern 10 and an insulating film 14 surrounding a surface (or outer circumferential surface) of the light-emitting stack pattern 10.

The light-emitting stack pattern 10 may include a first semiconductor layer 11, an active layer 12, a barrier layer 18, a second semiconductor layer 13, and an additional electrode 15 which may be sequentially stacked in a length L direction of the light-emitting element LD. Here, the active layer 12 and the barrier layer 18 may be included in an undoped region A of the light-emitting stack pattern 10. The first and second semiconductor layers 11 and 13 may be included in a doped region B of the light-emitting stack pattern 10.

The barrier layer 18 may be provided and/or formed and/or disposed between the active layer 12 and the second semiconductor layer 13. The barrier layer 18 may be divided into or may include a second region 18_2 including an oxide layer formed by oxidizing a portion of a surface during a manufacturing process and a first region 18_1 not including the oxide layer. The above-described barrier layer 18 may be the same component as the second barrier layer 17 described with reference to FIGS. 1 and 2.

In an embodiment, the barrier layer 18 may be made of any one semiconductor material selected from AlInP and AlGaAs. The barrier layer 18 may be made of a semiconductor material having a higher aluminum (Al) composition than the first and second semiconductor layers 11 and 13. Accordingly, in a case that the heat treatment method described with reference to FIG. 13 is performed, oxidation may gradually proceed from an edge of the barrier layer 18 (for example, one or a region of the barrier layer 18 in contact with an inner side surface 14d of the insulating film 14) to the inside (or center) thereof, thereby forming the second region 18_2 including the oxide layer.

As in an embodiment, in a case that the light-emitting element LD may include the barrier layer 18 including the second region 18_2 formed as the oxide layer, surface resistance in the undoped region A of the light-emitting stack pattern 10 may be relatively increased. Accordingly, a leakage current path on the surface of the light-emitting stack pattern 10 (or light-emitting element LD) may be blocked to minimize a surface leakage current, thereby improving luminous efficiency of the light-emitting element LD.

Hereinafter, an example of a display device using the above-described light-emitting element LD as a light source (or light-emitting source) will be described.

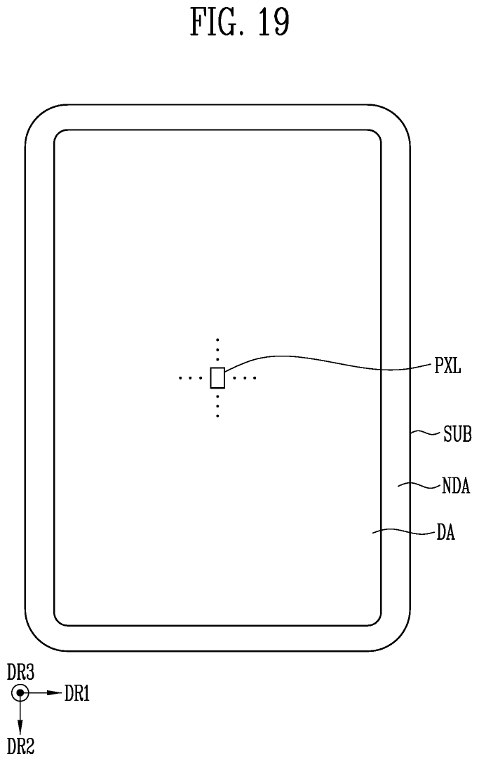

FIG. 19 illustrates a display device according to an embodiment, and for example, is a schematic plan view of a display device using the light-emitting element illustrated in FIGS. 1 and 2 as a light source.

In FIG. 19, for convenience, the structure of the display device is schematically illustrated based on a display area DA in which an image is displayed.

Referring to FIGS. 1, 2 and 19, the display device according to an embodiment may include a substrate SUB, a plurality of pixels PXL which may be provided or disposed on the substrate SUB and each may include at least one light-emitting element LD, a driver which may be provided or disposed on the substrate SUB and drives the pixels PXL, and a line portion which electrically connects the pixels PXL and the driver.

In a case that the display device is an electronic device, in which a display surface is applied to at least one surface thereof, such as a smartphone, a television, a tablet personal computer (PC), a mobile phone, an image phone, an e-book reader, a desktop PC, a laptop PC, a netbook computer, a workstation, a server, a personal digital assistant (PDA), a portable multimedia player (PMP), an MP3 player, a medical device, a camera, or a wearable device, the disclosure may be applied, however, the disclosure is not limited thereto.

The display device may be classified into a passive matrix type display device and an active matrix type display device according to a method of driving the light-emitting element LD. As an example, in a case that the display device is implemented as an active matrix type, each of the pixels PXL may include a driving transistor which controls an amount of a current supplied to the light-emitting element LD, a switching transistor which transmits a data signal to the driving transistor, and the like within the spirit and the scope of the disclosure.

The display device may be provided in various shapes, for example, a substantially rectangular plate shape having two pairs of sides parallel to each other, but the disclosure is not limited thereto. In a case that the display device is provided in the substantially rectangular plate shape, among the two pairs of sides, one pair of sides may be provided longer than the other pair of sides. For convenience, a case is illustrated in which the display device has a substantially rectangular shape having a pair of long sides and a pair of short sides. An extending direction of the long side may be expressed as a second direction DR2, an extending direction of the short side may be expressed as a first direction DR1, and a direction perpendicular to the extending directions of the long side and the short side may be expressed as a third direction DR3. In the display device provided in the substantially rectangular plate shape, a corner, at which one long side may be in contact with (or may meet) one short side, may have a substantially round shape, but the disclosure is not limited thereto.

The substrate SUB may include the display area DA and a non-display area NDA.

The display area DA may be an area in which the pixels PXL displaying an image may be provided or disposed. The non-display area NDA may be an area in which the driver for driving the pixels PXL and a portion of the line portion for electrically connecting the pixels PXL and the driver may be provided. For convenience, only one pixel PXL is illustrated in FIG. 19, but the plurality of pixels PXL may be substantially disposed in the display area DA of the substrate SUB.

The non-display area NDA may be provided on at least one or a side of the display area DA. The non-display area NDA may surround or may be adjacent to a periphery (or edge) of the display area DA. The line portion electrically connected to the pixels PXL and the driver electrically connected to the line portion and drives the pixels PXL may be provided or disposed in the non-display area NDA.

The line portion may electrically connect the driver and the pixels PXL. The line portion may provide a signal to each pixel PXL and may be a fan-out line portion electrically connected to signal lines, for example, a scan line, a data line, and an emission control line. For example, the line portion may be a fan-out line portion electrically connected to signal lines electrically connected to each pixel PXL, for example, a control line and a sensing line in order to compensate for changes in electrical characteristics of each pixel PXL in real time.

The substrate SUB may include a transparent insulating material to transmit light. The substrate SUB may be a rigid substrate or a flexible substrate.

One or an area of the substrate SUB may be provided as the display area DA, and thus, the pixels PXL may be disposed therein. The remaining area of the substrate SUB may be provided as the non-display area NDA. As an example, the substrate SUB may include the display area DA including pixel areas in which the pixels PXL may be disposed and include the non-display area NDA disposed around (or adjacent to) the display area DA.

The pixels PXL may each be provided or disposed in the display area DA of the substrate SUB. In an embodiment, the pixels PXL may be arranged or disposed in the display area DA in a stripe arrangement structure or a pentile arrangement structure, but the disclosure is not limited thereto.

Each pixel PXL may include at least one light-emitting element LD driven by a corresponding scan signal and data signal. The light-emitting element LD may have a small size ranging from a nanoscale to a microscale and may be electrically connected parallel with light-emitting elements disposed adjacent thereto, but the disclosure is not limited thereto. The light-emitting element LD may constitute a light source of each pixel PXL.

Each pixel PXL may include at least one light source, for example, the light-emitting element LD illustrated in FIGS. 1 and 2 driven by certain or predetermined signals (for example, a scan signal and a data signal) and/or certain or predetermined powers (for example, first driving power and second driving power). However, in embodiments, the type of the light-emitting element LD usable as the light source of each pixel PXL is not limited thereto.

The driver may provide a certain or predetermined signal and certain or predetermined power to each pixel PXL through the line portion, thereby controlling the driving of the pixel PXL. The driver may include a scan driver, an emission driver, a data driver, and a timing controller.

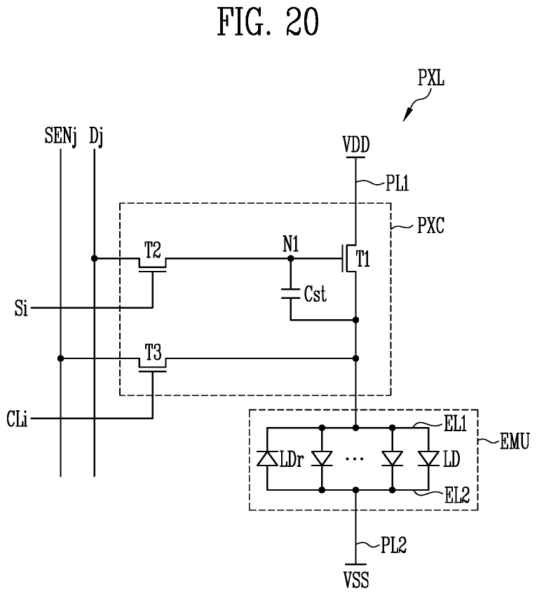

FIG. 20 is an equivalent circuit diagram illustrating an electrical connection relationship between components included in one pixel illustrated in FIG. 19 according to an embodiment.

For example, FIG. 20 illustrates an electrical connection relationship between components included in a pixel PXL applicable to an active type display device according to an embodiment. However, the types of the components included in the pixel PXL to which an embodiment is applicable are not limited thereto.

In FIG. 20, not only components included in each of the pixels illustrated in FIG. 19 but also an area in which the components are provided are collectively referred to as the pixel PXL.

Referring to FIGS. 1, 2, 19, and 20, one pixel PXL (hereinafter, referred to as “pixel”) may include a light-emitting unit EMU which generates light having luminance corresponding to a data signal. For example, the pixel PXL may further optionally include a pixel circuit PXC for driving the light-emitting unit EMU.

According to embodiments, the light-emitting unit EMU may include a plurality of light-emitting elements LD electrically connected in parallel with each other between a first power line PL1 to which a voltage of a first driving power source VDD is applied and a second power line PL2 to which a voltage of a second driving power source VSS may be applied. For example, the light-emitting unit EMU may include a first electrode EL1 (or “first alignment electrode”) electrically connected to the first driving power source VDD through the pixel circuit PXC and the first power line PL1, a second electrode EL2 (or “second alignment electrode”) electrically connected to the second driving power source VSS through the second power line PL2, and the plurality of light-emitting elements LD electrically connected in parallel with each other in the same direction between the first electrode EL1 and the second electrode EL2. In an embodiment, the first electrode EL1 may be an anode, and the second electrode EL2 may be a cathode.

Each of the light-emitting elements LD included in the light-emitting unit EMU may include one or an end portion electrically connected to the first driving power source VDD through the first electrode EL1 and the other or another end portion electrically connected to the second driving power source VSS through the second electrode EL2. The first driving power source VDD and the second driving power source VSS may have different potentials. As an example, the first driving power source VDD may be set as a high potential power source, and the second driving power source VSS may be set as a low potential power source. In this case, a potential difference between the first driving power source VDD and the second driving power source VSS may be set to be greater than or equal to a threshold voltage of the light-emitting elements LD during an emission period of the pixel PXL.

As described above, each of the light-emitting elements LD electrically connected in parallel with each other in the same direction (for example, a forward direction) between the first electrode EL1 and the second electrode EL2, to which voltages having different potentials may be supplied, may constitute each effective light source. The effective light sources may be clustered to constitute the light-emitting unit EMU of the pixel PXL.

The light-emitting elements LD of the light-emitting unit EMU may emit light having luminance corresponding to a driving current supplied through the corresponding pixel circuit PXC. For example, during each frame period, the pixel circuit PXC may supply a driving current corresponding to a gradation value of corresponding frame data to the light-emitting unit EMU. The driving current supplied to the light-emitting unit EMU may be divided to flow in the light-emitting elements LD. Accordingly, while each light-emitting element LD emits light at luminance corresponding to a current flowing therein, the light-emitting unit EMU may emit light at luminance corresponding to the driving current.

Meanwhile, an embodiment is illustrated in which both end portions of the light-emitting elements LD may be electrically connected in the same direction between the first driving power source VDD and the second driving power source VSS, but the disclosure is not limited thereto. According to embodiments, the light-emitting unit EMU may further include at least one ineffective light source, for example, a reverse light-emitting element LDr, in addition to the light-emitting-elements LD constituting the effective light sources. The reverse light-emitting element LDr may be electrically connected in parallel with the light-emitting elements LD constituting the effective light sources between the first electrode EL1 and the second electrode EL2 and may be electrically connected between the first electrode EL1 and the second electrode EL2 in an opposite direction as the light-emitting elements LD. The reverse light-emitting element LDr may maintain an inactive state even in a case that a certain or predetermined driving voltage (for example, a driving voltage in a forward direction) may be applied between the first electrode EL1 and the second electrode EL2, and thus, a current may not substantially flow in the reverse light-emitting element LDr.

The pixel circuit PXC may be electrically connected to a scan line Si and a data line Dj of the corresponding pixel PXL. As an example, in a case that the pixel PXL may be disposed in an i^{th} row and a j^{th} column of a display area DA (wherein i is a natural number and j is a natural number), the pixel circuit PXC of the pixel PXL may be electrically connected to an i^{th} scan line Si and a jth data line Dj of the display area DA. For example, the pixel circuit PXC may be electrically connected to an i^{th} control line CLi and a jth sensing line SENj of the display area DA.

The above-described pixel circuit PXC may include first to third transistors T1 to T3 and a storage capacitor Cst.

A first terminal of the first transistor T1 (driving transistor) may be electrically connected to the first driving power source VDD, and a second terminal thereof may be electrically connected to the first electrode EL1 of each of the light-emitting elements LD. A gate electrode of the first transistor T1 may be electrically connected to a first node N1. The first transistor T1 may control an amount of a driving current supplied to the light-emitting elements LD in response to a voltage of the first node N1. A first terminal of the second transistor T2 (switching transistor) may be electrically connected to the j^{th} data line Dj, and a second terminal thereof may be electrically connected to the first node N1. Here, the first terminal and the second terminal of the second transistor T2 may be different terminals, and for example, in a case that the first terminal may be a source electrode, the second terminal may be a drain electrode. A gate electrode of the second transistor T2 may be electrically connected to the i^{th} scan line Si.

The second transistor T2 may be turned on in a case that a scan signal having a voltage, at which the second transistor T2 may be turned on, may be supplied from the i^{th} scan line Si, thereby electrically connecting the jₜₕ data line Dj and the first node N1. In this case, a data signal of a corresponding frame may be supplied to the j^{th} data line Dj, and thus, the data signal may be transmitted to the first node N1. The data signal transmitted to the first node N1 may be charged in the storage capacitor Cst.

The third transistor T3 may be electrically connected between the first transistor T1 and the j^{th} sensing line SENj. For example, a first terminal of the third transistor T3 may be electrically connected to the first terminal (for example, a source electrode) of the first transistor T1 electrically connected to the first electrode EL1, and a second terminal of the third transistor T3 may be electrically connected to the j^{th} sensing line SENj. A gate electrode of the third transistor T3 may be electrically connected to the i^{th} control line CLi. The third transistor T3 may be turned on by a control signal having a gate-on voltage supplied to the i^{th} control line CLi during a certain or predetermined sensing period, thereby electrically connecting the j^{th} sensing line SENj and the first transistor T1.

The sensing period may be a period for extracting characteristic information (for example, a threshold voltage or the like of the first transistor T1) of each of the pixels PXL disposed in the display area DA.

One or an electrode of the storage capacitor Cst may be electrically connected to the first driving power source VDD, and the other electrode thereof may be electrically connected to the first node N1. The storage capacitor Cst may be charged with a voltage corresponding to a data signal supplied to the first node Ni and may maintain the charged voltage until a data signal of a next frame may be supplied.

FIG. 20 illustrates an embodiment in which all of the first to third transistors T1 to T3 are n-type transistors, but the disclosure is not limited thereto. For example, at least one of the above-described first to third transistors T1 to T3 may be changed to a p-type transistor. For example, FIG. 20 illustrates an embodiment in which the light-emitting unit EMU may be electrically connected between the pixel circuit PXC and the second driving power source VSS, but the light-emitting unit EMU may be electrically connected between the first driving power source VDD and the pixel circuit PXC.

The structure of the pixel circuit PXC may be variously changed and implemented. As an example, the pixel circuit PXC may further additionally include other circuit elements such as at least one transistor element of a transistor element for initializing the first node N1 and/or a transistor element for controlling emission times of the light-emitting elements LD, and a boosting capacitor for boosting a voltage of the first node Ni.

For example, FIG. 20 illustrates an embodiment in which the light-emitting elements LD constituting the light-emitting unit EMU are all electrically connected in parallel, but the disclosure is not limited thereto. According to embodiments, the light-emitting unit EMU may include at least one series stage including a plurality of light-emitting elements LD electrically connected in parallel with each other. For example, the light-emitting unit EMU may also have a series-and-parallel mixed structure.

The structure of the pixel PXL applicable to the disclosure is not limited to an embodiment illustrated in FIG. 20, and the pixel PXL may have various structures. For example, each pixel PXL may be provided inside of a passive light-emitting display device. In this case, the pixel circuit PXC may be omitted, and both end portions of the light-emitting elements LD included in the light-emitting unit EMU may be electrically connected directly to the i^{th} scan line Si, the i^{th} data line Dj, the first power line PL1 to which the first driving power source VDD may be electrically connected, the second power line PL2 to which the second driving power source VSS may be electrically connected, and/or a certain or predetermined control line.

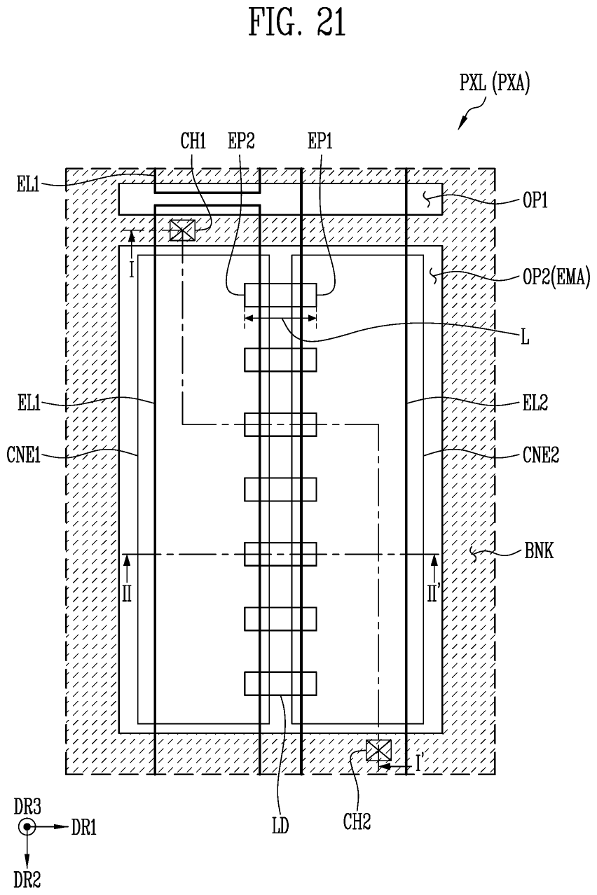

FIG. 21 is a schematic plan view illustrating one pixel of the pixels illustrated in FIG. 19.

In FIG. 21, for convenience, the illustration of transistors T electrically connected to light-emitting elements LD and signal lines electrically connected to the transistors T is omitted.

In an embodiment, for convenience of description, a lateral direction (or horizontal direction) in a plan view is expressed as a first direction DR1, a longitudinal direction (or vertical direction) in a plan view is expressed as a second direction DR2, and a thickness direction of a substrate SUB in a cross section is expressed as a third direction DR3. The first to third directions DR1, DR2, and DR3 may refer to directions indicated by the first to third directions DR1, DR2, and DR3, respectively.

Referring to FIG. 21, each pixel PXL may be provided and/or formed and/or disposed in a pixel area PXA provided in the substrate SUB. The pixel area PXA may include an emission area EMA and a peripheral area. In an embodiment, the peripheral area may include a non-emission area from which light may not be emitted.

According to embodiments, each pixel PXL may include a bank BNK positioned or disposed in the peripheral area.

The bank BNK may be a structure defining (or partitioning) the pixel area PXA or the emission area EMA of each of the corresponding pixel PXL and adjacent pixels PXL and may be, for example, a pixel definition film In an embodiment, in a process of supplying the light-emitting elements LD to each pixel PXL, the bank BNK may be a pixel definition film or a dam structure defining each emission area EMA to which the light-emitting elements LD may be supplied. As an example, the emission area EMA of each pixel PXL may be partitioned by the bank BNK, and thus, a mixed solution (for example, ink) including the desired amount and/or type of the light-emitting element LD may be supplied (or introduced) to the emission area EMA.

The bank BNK may include at least one light blocking material and/or reflective material to prevent light leakage defects in which light (or ray) may leak between each pixel PXL and adjacent pixels PXL. According to embodiments, the bank BNK may include a transparent material (or substance). The transparent material may include, for example, a polyamide-based resin, a polyimide-based rein, or the like, but the disclosure is not limited thereto. According to an embodiment, a reflective material layer may be separately provided and/or formed and/or disposed on the bank BNK in order to further improve efficiency of light emitted from each pixel PXL.

The bank BNK may include one or more openings exposing components positioned under or below the bank BNK in the pixel area PXA of the corresponding pixel PXL. As an example, the bank BNK may include a first opening OP1 and a second opening OP2 exposing the components positioned under or below the bank BNK in the pixel area PXA of the corresponding pixel PXL. According to an embodiment, the emission area EMA of each pixel PXL and the second opening OP2 of the bank BNK may substantially correspond to each other.

In the pixel area PXA, the first opening OP1 of the bank BNK may be positioned to be spaced apart from the second opening OP2 and may be positioned adjacent to one or a side (for example, an upper or lower side) of the pixel area PXA. As an example, the first opening OP1 of the bank BNK may be positioned adjacent to the upper side of the pixel area PXA.

Each pixel PXL may include a first electrode EL1 and a second electrode EL2 spaced apart from each other in the first direction DR1. The first electrode EL1 may correspond to the first electrode EL1 described with reference to FIG. 20, and the second electrode EL2 may correspond to the second electrode EL2 described with reference to FIG. 20.

After the light-emitting elements LD are supplied and aligned in the pixel area PXA in a process of manufacturing a display device, the first electrode EL1 may be separated from another electrode (for example, a first electrode (not illustrated) provided to each of the adjacent pixels PXL adjacent in the second direction DR2) in the first opening OP1. For example, the first opening OP1 of the bank BNK may be provided for a process of separating the first electrode ELL

The first electrode EL1 may be electrically connected to the first transistor T1 described with reference to FIG. 20 through a first contact hole CH1, and the second electrode EL2 may be electrically connected to the second driving power source VSS (or second power line PL2) described with reference to FIG. 20 through a second contact hole CH2.

The first electrode EL1 and the second electrode EL2 may have a multi-layered structure including a reflective electrode and a conductive capping layer. For example, the reflective electrode may have a single-layered or multi-layered structure. As an example, the reflective electrode may include at least one opaque metal layer and may optionally further include at least one transparent conductive layer disposed on and/or below the opaque metal layer.

Each pixel PXL may include a plurality of light-emitting elements LD. According to embodiments, each pixel PXL may further include the reverse light-emitting element LDr described with reference to FIG. 20.

The light-emitting elements LD may be disposed between the first electrode EL1 and the second electrode EL2. Each of the light-emitting elements LD may include a first end portion EP1 (or one end portion) and a second end portion EP2 (or the other end portion) positioned at both end portions in a length L direction thereof. In an embodiment, an n-type semiconductor layer may be positioned or disposed at the first end portion EP1, and an additional electrode (see 15 of FIG. 1) in ohmic contact with a p-type semiconductor layer may be positioned or disposed at the second end portion EP2. Here, the p-type semiconductor layer may be the second semiconductor layer 13 described with reference to FIG. 1, and the n-type semiconductor layer may be the first semiconductor layer 11 described with reference to FIG. 1. The light emitting elements LD may be electrically connected in parallel with each other between the first electrode EL1 and the second electrode EL2. Each of the light-emitting elements LD may have the same component as the light-emitting element LD described with reference to FIGS. 1 and 2.

In an embodiment, the second end portion EP2 of each of the light-emitting elements LD may be not be provided directly on the first electrode EL1 but may be electrically connected to the first electrode EL1 through at least one contact electrode, for example, a first contact electrode CNE1. For example, the first end portion EP1 of each of the light-emitting elements LD may not be provided directly on the second electrode EL2 but may be electrically connected to the second electrode EL2 through at least another contact electrode, for example, a second contact electrode CNE2.

Each of the light-emitting elements LD may be a light-emitting diode having a micro size, for example, a small size ranging from a nanoscale to a microscale by using a material having an inorganic crystal structure.

At least two to tens of the light-emitting elements LD may be aligned and/or provided in the emission area EMA of each pixel PXL, but the number of the light-emitting elements LD is not limited thereto. According to an embodiment, the number of the light-emitting elements LD arranged and/or provided and/or disposed in the emission area EMA may be variously changed.

Each of the light-emitting elements LD may emit any one of color light and/or white light. Each of the light-emitting elements LD may be aligned between the first electrode EL1 and the second electrode EL2 such that an extending direction (or length L direction) thereof may be parallel to the first direction DR1. The light-emitting elements LD may be provided in a shape sprayed in a solution and may be introduced (or supplied) to the emission area EMA of each pixel PXL.

The light-emitting elements LD may be introduced (or supplied) to the emission area EMA of each pixel PXL through an inkjet printing method, a slit coating method, or various other methods. As an example, the light-emitting elements LD may be mixed into a volatile solvent and introduced (or supplied) to the emission area EMA through the inkjet printing method or the slit coating method. In this case, in a case that a corresponding alignment signal is applied to the first electrode EL1 and the second electrode EL2, an electric field may be formed between the first electrode EL1 and the second electrode EL2. As a result, the light-emitting elements LD may be aligned between the first electrode EL1 and the second electrode EL2. By volatilizing the solvent or removing the solvent through other methods after the light-emitting elements LD are aligned, the light-emitting elements LD may be stably aligned between the first electrode EL1 and the second electrode EL2.

According to embodiments, each pixel PXL may include the first contact electrode CNE1 and the second contact electrode CNE2.

The first contact electrode CNE1 may be provided and/or formed and/or disposed on the second end portion EP2 of each of the light-emitting elements LD and on a region of the first electrode EL1 corresponding thereto, thereby physically and/or electrically connecting the second end portion EP2 of each of the light-emitting elements LD to the first electrode ELL The first contact electrode CNE1 may be provided and/or formed and/or disposed on the first electrode EL1 to overlap the first electrode ELL The first contact electrode CNE1 may have a substantially bar-like shape extending in the second direction DR2 in a plan view, but the disclosure is not limited thereto. According to embodiments, the shape of the first contact electrode CNE1 may be variously changed within a range in which the first contact electrode CNE1 is electrically and stably electrically connected to each of the light-emitting elements LD. For example, the shape of the first contact electrode CNE1 may be variously changed in consideration of a connection relationship with the first electrode EL1 disposed under or below the first contact electrode CNE1.

The second contact electrode CNE2 may be provided and/or formed and/or disposed on the first end portion EP1 of each of the light-emitting elements LD and on a region of the second electrode EL2 corresponding thereto, thereby physically and/or electrically connecting the first end portion EP1 of each of the light-emitting elements LD to the second electrode EL2. The second contact electrode CNE2 may be provided and/or formed and/or disposed on the second electrode EL2 to overlap the second electrode EL2. The second contact electrode CNE2 may have a substantially bar-like shape extending in the second direction DR2 in a plan view, but the disclosure is not limited thereto. According to embodiments, the shape of the second contact electrode CNE2 may be variously changed within a range in which the second contact electrode CNE2 is electrically and stably electrically connected to each of the light-emitting elements LD. For example, the shape of the second contact electrode CNE2 may be variously changed in consideration of a connection relationship with the second electrode EL2 disposed under or below the second contact electrode CNE2.

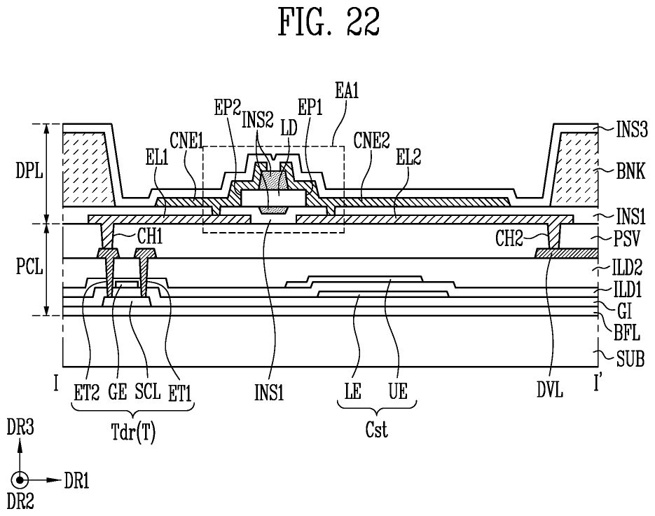

Hereinafter, the stacked structure of each pixel PXL according to the above-described embodiment will be described with reference to FIGS. 22 to 25.

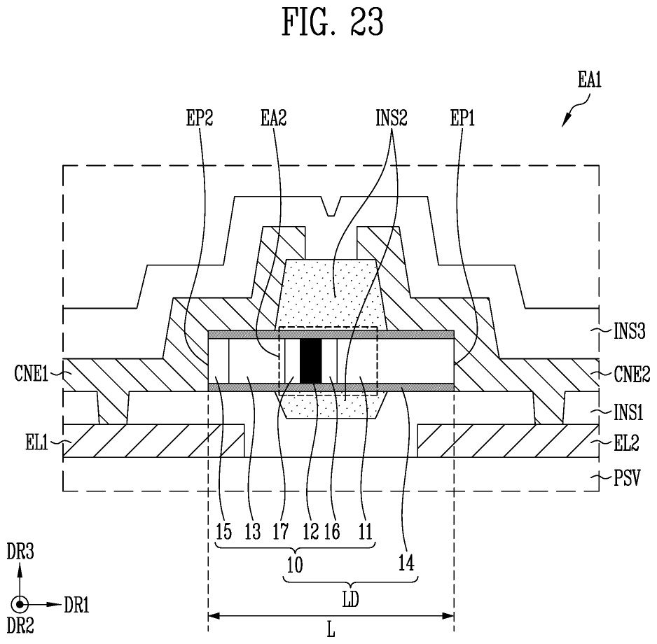

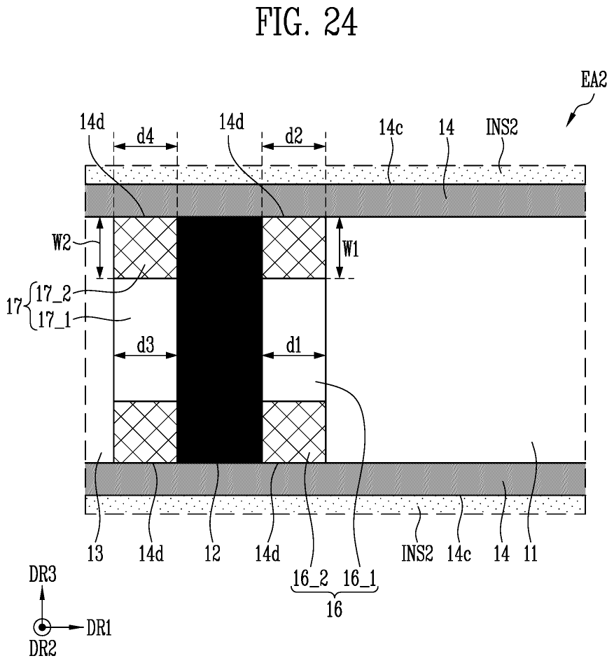

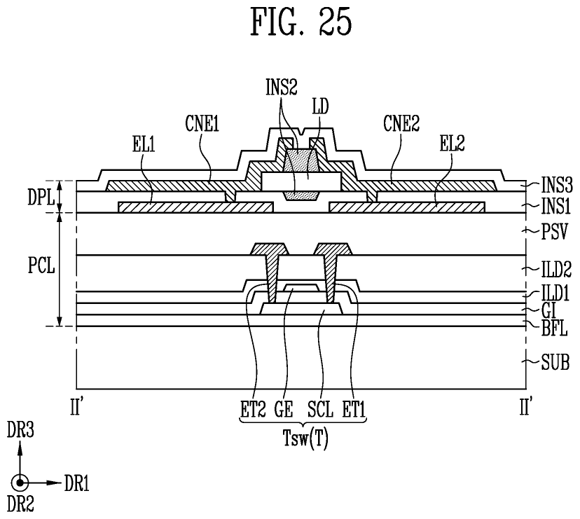

FIG. 22 is a schematic cross-sectional view taken along line I-I′ of FIG. 21. FIG. 23 is a schematic enlarged schematic cross-sectional view of portion EA1 of FIG. 22. FIG. 24 is a schematic enlarged schematic cross-sectional view of portion EA2 of FIG. 24. FIG. 25 is a schematic cross-sectional view taken along line II-II′ of FIG. 21.

In FIGS. 22 to 25, one pixel PXL is simplified and illustrated in such a manner that each electrode is illustrated as a single-film electrode and each insulating layer is illustrated only as a single-film insulating layer, but the disclosure is not limited thereto.

Referring to FIGS. 21 to 25, the pixel PXL may include a substrate SUB, a pixel circuit layer PCL, and a display element layer DPL.

The substrate SUB may include a transparent insulating material to transmit light. The substrate SUB may be a rigid substrate or a flexible substrate.

The rigid substrate may be, for example, one of an organic substrate, a quartz substrate, a glass ceramic substrate, and a crystalline glass substrate.

The flexible substrate may be one of a film substrate and a plastic substrate which may include a polymer organic material. For example, the flexible substrate may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The pixel circuit layer PCL may include a buffer layer BFL, at least one transistor T, at least one storage capacitor Cst, and a passivation layer PSV.

The buffer layer BFL may prevent impurities from being diffused into the transistor T included in the pixel circuit (see “PXC” of FIG. 20). The buffer layer BFL may be an inorganic insulating film including an inorganic material. The buffer layer BFL may include at least one selected from metal oxides such as silicon nitride (SiNₓ), silicon oxide (SiOₓ), silicon oxynitride (SiOₓN_{y}), and aluminum oxide (AlOₓ). The buffer layer BFL may be provided as a single-film but may also be provided as a multi-film including at least two films In a case that the buffer layer BFL is provided as the multi-film, respective layers may be made of the same or similar material or may be made of different materials. The buffer layer BFL may be omitted according to the material and process conditions of the substrate SUB.

The transistor T may include a driving transistor Tdr for controlling a driving current of the light-emitting elements LD and a switching transistor Tsw electrically connected to the driving transistor Tdr. However, the disclosure is not limited thereto, and the pixel circuit PXC may further include circuit elements that may perform other functions in addition to the driving transistor Tdr and the switching transistor Tsw. The driving transistor Tdr may be the first transistor T1 described with reference to FIG. 20, and the switching transistor Tsw may be the second transistor T2 described with reference to FIG. 20. In the following embodiments, the driving transistor Tdr and the switching transistor Tsw will be collectively referred to as a transistor T or transistors T.

Each of the driving transistor Tdr and the switching transistor Tsw may include a semiconductor pattern SCL, a gate electrode GE, a first terminal ET1, and a second terminal ET2. The first terminal ET1 may be any one electrode of a source electrode and a drain electrode, and the second terminal ET2 may be the other electrode.

The semiconductor pattern SCL may be provided and/or formed and/or disposed on the buffer layer BFL. The semiconductor pattern SCL may include a first contact region in contact with the first terminal ET1 and a second contact region in contact with the second terminal ET2. A region between the first contact region and the second contact region may be a channel region. The channel region may overlap the gate electrode GE of the corresponding transistor T. The semiconductor pattern SCL may be a semiconductor pattern made of poly silicon, amorphous silicon, an oxide semiconductor, or the like within the spirit and the scope of the disclosure. The channel region may be, for example, a semiconductor pattern that may not be doped with impurities and may be an intrinsic semiconductor. The first contact region and the second contact region may be semiconductor patterns doped with impurities.

The gate electrode GE may be provided and/or formed and/or disposed on a gate insulating layer GI to correspond to the channel region of the semiconductor pattern SCL. The gate electrode GE may be provided or disposed on the gate insulating layer GI to overlap the channel region of the semiconductor pattern SCL. The gate electrode GE may have a single-film structure made of one selected from the group consisting of copper (Cu), molybdenum (Mo), tungsten (W), aluminum neodymium (AlNd), titanium (Ti), aluminum (Al), silver (Ag), and an alloy thereof, or a mixture thereof or may have a double-film or multi-film structure including a low resistance material, such as molybdenum (Mo), titanium (Ti), copper (Cu), aluminum (Al), or silver (Ag) in order to reduce line resistance.

The gate insulating layer GI may be an inorganic insulating film including an inorganic material. As an example, the gate insulating layer GI may include at least one selected from metal oxides such as silicon nitride (SiNₓ), silicon oxide (SiOₓ), silicon oxynitride (SiOₓN_{y}), and aluminum oxide (AlOₓ). However, the material of the gate insulating layer GI is not limited to the above-described embodiments. According to embodiments, the gate insulating layer GI may be formed as an organic insulating film including an organic material. The gate insulating layer GI may be provided as a single-film, but may also be provided as a multi-film including at least two films.

The first terminal ET1 and the second terminal ET2 may be provided and/or formed and/or disposed on a second interlayer insulating layer ILD2 and may contact the first contact region and the second contact region of the semiconductor pattern SCL through contact holes sequentially passing through the gate insulating layer GI and first and second interlayer insulating layers ILD1 and ILD2. As an example, the first terminal ET1 may be in contact with the first contact region of the semiconductor pattern SCL, and the second terminal ET2 may be in contact with the second contact region of the semiconductor pattern SCL. Each of the first and second terminals ET1 and ET2 may include the same or similar material as the gate electrode GE or may include at least one material selected from the materials described as structure materials of the gate electrode GE.

The first interlayer insulating layer ILD1 may include the same or similar material as the gate electrode GE or may include at least one selected from the materials described as structure materials of the gate electrode GE.

The second interlayer insulating layer ILD2 may be provided and/or formed and/or disposed on the first interlayer insulating layer ILD1. The second interlayer insulating layer ILD2 may be an inorganic insulating film including an inorganic material or an organic insulating film including an organic material. According to embodiments, the second interlayer insulating layer ILD2 may include the same or similar material as the first interlayer insulating layer ILD1, but the disclosure is not limited thereto. The second interlayer insulating layer ILD2 may be provided as a single-film but may also be provided as a multi-film including at least two films.

In the above-described embodiment, it has been described that the first and second terminals ET1 and ET2 of the transistor T are separate electrodes electrically connected to the semiconductor pattern SCL through the contact holes sequentially passing through the gate insulating layer GI and the first and second interlayer insulating layers ILD1 and ILD2, but the disclosure is not limited thereto. According to embodiments, the first terminal ET1 of the transistor T may be a first contact region adjacent to the channel region of the corresponding semiconductor pattern SCL, and the second terminal ET2 of the transistor T may be a second contact region adjacent to the channel region of the corresponding semiconductor pattern SCL. In this case, the second terminal ET2 of the transistor T may be electrically connected to the light-emitting elements LD of the corresponding pixel PXL through a separate connection means such as a bridge electrode or the like within the spirit and the scope of the disclosure.

In an embodiment, the transistors T may be formed as low temperature polysilicon thin film transistors, but the disclosure is not limited thereto. According to embodiments, the transistors T may be formed as oxide semiconductor thin film transistors. Furthermore, in the above-described embodiment, a case where the transistors T are thin film transistors having a top gate structure has been described as an example, but the disclosure is not limited thereto. The structure of the transistors T may be variously changed.

The storage capacitor Cst may include a lower electrode LE provided or disposed on the gate insulating layer GI and an upper electrode UE provided or disposed on the first interlayer insulating layer ILD1 to overlap the lower electrode LE.

The lower electrode LE may be provided or disposed on the same layer as the gate electrode GE of the driving transistor Tdr and may include the same or similar material as the gate electrode GE. The lower electrode LE may be integrally provided or integral with the gate electrode GE of the driving transistor Tdr. In this case, the lower electrode LE may be regarded as one or a region of the gate electrode GE of the driving transistor Tdr. According to embodiments, the lower electrode LE may be provided as a component that may be separate from (or non-integral with) the gate electrode GE of the driving transistor Tdr. In this case, the lower electrode LE and the gate electrode GE of the driving transistor Tdr may be electrically connected through a separate connection means.

The upper electrode UE may overlap the lower electrode LE and may cover or overlap the lower electrode LE. A capacitance of the storage capacitor Cst may be increased by increasing an overlapping area of the upper electrode UE and the lower electrode LE. The upper electrode UE may be electrically connected to the first power line (see “PL1” of FIG. 20). The storage capacitor Cst may be covered or overlapped by the second interlayer insulating layer ILD2.

The pixel circuit layer PCL may include a driving voltage line DVL provided and/or formed and/or disposed on the second interlayer insulating layer ILD2. The driving voltage line DVL may be the same component as the second power line PL2 described with reference to FIG. 20. Accordingly, a voltage of a second driving power source VSS may be applied to the driving voltage line DVL. The pixel circuit layer PCL may further include the first power line PL1 electrically connected to a first driving power source VDD. Although not illustrated directly in the drawings, the first power line PL1 may be provided on the same layer as the driving voltage line DVL or on a different layer from the driving voltage line DVL. In the above-described embodiment, it has been described that the driving voltage line DVL is provided or disposed on the same layer as the first and second terminals ET1 and ET2 of the transistors T, but the disclosure is not limited thereto. According to embodiments, the driving voltage line DVL may be provided or disposed on the same layer as any one conductive layer of conductive layers provided in the pixel circuit layer PCL. For example, the position of the driving voltage line DVL in the pixel circuit layer PCL may be variously changed.

Each of the first power line PL1 and the driving voltage line DVL may include a conductive material (substance). As an example; each of the first power line PL1 and the driving voltage line DVL may have a single-film structure made of one selected from the group consisting of copper (Cu), molybdenum (Mo), tungsten (W), aluminum neodymium (AlNd), titanium (Ti), aluminum (Al), silver (Ag), and an alloy thereof, or a mixture thereof or may have a double-film or multi-film structure including a low resistance material, such as molybdenum (Mo), titanium (Ti), copper (Cu), aluminum (Al), or silver (Ag) in order to reduce line resistance. As an example, each of the first power line PL1 and the driving voltage line DVL may be formed as a double-film in which titanium (Ti) and copper (Cu) may be sequentially stacked.

The first power line PL1 may be electrically connected to some or a number of components of the display element layer DPL, for example, the first electrode EL1, and the driving voltage line DVL may be electrically connected to other components of the display element layer DPL, for example, the second electrode EL2.

The passivation layer PSV may be provided and/or formed and/or disposed on the transistors T and the driving voltage line DVL.

The passivation layer PSV may be provided in the form of an organic insulating film, an inorganic insulating film, or an organic insulating film disposed on an inorganic insulating film. The inorganic insulating film may include, for example, at least one selected from metal oxides such as silicon oxide (SiOₓ), silicon nitride (SiNₓ), silicon oxynitride (SiOₓN_{y}), and aluminum oxide (AlOₓ). The organic insulating film may include, for example, at least one selected from an acrylic-based resin (polyacrylate-based resin), an epoxy-based resin, a phenolic-based resin, a polyamide-based resin, a polyimide-based resin, an unsaturated polyester-based resin, a polyphenylene ether-based resin, a polyphenylene sulfide-based resin, and a benzocyclobutene resin.

The passivation layer PSV may include a first contact hole CH1 exposing the second terminal ET2 of the driving transistor Tdr and a second contact hole CH2 exposing the driving voltage line DVL.

The display element layer DPL may be provided on the passivation layer PSV.

The display element layer DPL may include the bank BNK, the first and second electrodes EL1 and EL2, the light-emitting elements LD, the first and second contact electrodes CNE1 and CNE2, and first to third insulating layers INS1 to INS3.

The bank BNK may be provided and/or formed and/or disposed on the first insulating layer INS1 and may define (or partition) the emission area EMA of the corresponding pixel PXL. The bank BNK may include the first opening OP1 and the second opening OP2 spaced apart from the first opening OP1. The second opening OP2 of the bank BNK may correspond to the emission area EMA of each of the pixels PXL.

The first electrode EL1 and the second electrode EL2 may be disposed to be spaced apart from each other in the first direction DR1. An end portion of the first electrode EL1 may be positioned in the first opening OP1 of the bank BNK. After the light-emitting elements LD are supplied and aligned in the pixel area PXA of the corresponding pixel PXL in a process of manufacturing a display device, the first electrode EL1 may be separated from another electrode (for example, the first electrode (not illustrated) provided to each of the adjacent pixels PXL adjacent in the second direction DR2 in a plan view) in the first opening OP1. The first opening OP1 of the bank BNK may be provided for a process of separating the first electrode ELL

In the above-described embodiment, it has been described that only the first electrode EL1 is separated from another electrode in the first opening OP1 of the bank BNK, but the disclosure is not limited thereto. According to embodiments, the first electrode EL1 may be separated from another electrode (for example, the second electrode (not illustrated) provided to the adjacent pixels PXL adjacent in the second direction DR2) in the first opening OP1. In this case, the first opening OP1 of the bank BNK may be provided for a process of separating the first electrode EL1 and the second electrode EL2.

Each of the first electrode EL1 and the second electrode EL2 may be made of a material having certain or predetermined reflectance to allow light emitted from each of the light-emitting elements LD to travel in an image display direction (for example, a front direction) of a display device. As an example, each of the first and second electrodes EL1 and EL2 may be made of a conductive material (or material) having certain or predetermined reflectance. The conductive substance (or material) may include an opaque metal that may be advantageous in reflecting light emitted from the light-emitting elements LD in an image display direction of a display device. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), or an alloy thereof. According to embodiments, each of the first and second electrodes EL1 and EL2 may include a transparent conductive substance (or material). The transparent conductive substance (or material) may include a conductive material such as indium tin oxide (ITO), indium zinc oxide (IZO), zinc oxide (ZnO), indium gallium zinc oxide (IGZO), or indium tin zinc oxide (ITZO), or a conductive polymer such as poly(3,4-ethylenedioxythiophene) (PEDOT). In a case that the first and second electrodes EL1 and EL2 include the transparent conductive substance (or material), a separate conductive layer made of an opaque metal may be added to reflect light emitted from the light-emitting elements LD in an image display direction of a display device. However, the material of the first and second electrodes EL1 and EL2 is not limited to the above-described materials.

Furthermore, each of the first and second electrodes EL1 and EL2 may be provided and/or formed and/or disposed as a single-film, but the disclosure is not limited thereto. According to embodiments, each of the first and second electrodes EL1 and EL2 may be provided and/or formed and/or disposed as a multi-film in which at least two materials selected from metals, alloys, conductive oxides, and conductive polymers may be stacked. In order to minimize distortion due to signal delay in a case that a signal (or voltage) may be transmitted to both end portions EP1 and EP2 of each of the light-emitting elements LD, each of the first and second electrodes EL1 and EL2 may be formed as a multi-film including at least two films. As an example, each of the first and second electrodes EL1 and EL2 may be formed as a multi-film in which indium tin oxide (ITO), silver (Ag), and ITO may be sequentially stacked.

The first electrode EL1 may be electrically connected to the driving transistor Tdr of the pixel circuit layer PCL through the first contact hole CH1 of the passivation layer PSV, and the second electrode EL2 may be electrically connected to the driving voltage line DVL of the pixel circuit layer PCL through the second contact hole CH2 of the passivation layer PSV. The first and second electrodes EL1 and EL2 may be used as alignment electrodes for aligning the light-emitting elements LD in each pixel PXL. Furthermore, the first and second electrodes EL1 and EL2 may be used as driving electrodes for driving the light-emitting elements LD after the light-emitting elements LD are aligned.

The first insulating layer INS1 may be provided and/or formed and/or disposed on the first electrode EL1 and the second electrode EL2.

The first insulating layer INS1 may include an inorganic insulating film made of an inorganic material or an organic insulating film made of an organic material. The first insulating layer INS1 may be formed as the inorganic insulating film that may be advantageous in protecting the light-emitting elements LD from the pixel circuit layer PCL. As an example, the first insulating layer INS1 may include at least one selected from metal oxides such as silicon nitride (SiNₓ), silicon oxide (SiOₓ), silicon oxynitride (SiOₓN_{y}), and aluminum oxide (AlOₓ), but the disclosure is not limited thereto. According to embodiments, the first insulating layer INS1 may be formed as the organic insulating film that may be advantageous in planarizing support surfaces of the light-emitting elements LD.

The first insulating layer INS1 may be provided and/or formed and/or disposed on the passivation layer PSV to entirely cover or overlap the first electrode EL1 and the second electrode EL2. After the light-emitting elements LD are supplied and aligned on the first insulating layer INS1, as illustrated in FIGS. 22, 23, and 25, the first insulating layer INS1 may be partially opened to expose one or a region of each of the first and second electrodes EL1 and EL2. After the light-emitting elements LD are supplied and aligned, the first insulating layer INS1 may be patterned in the form of an individual pattern that may be locally disposed only below the light-emitting elements LD. The first insulating layer INS1 may cover or overlap the remaining regions excluding one region of each of the first and second electrode EL1 and EL2. The first insulating layer INS1 may be omitted according to embodiments.

The bank BNK may be provided and/or formed and/or disposed on the first insulating layer INS1. The bank BNK may be formed provided and/or disposed between other pixels PXL so as to surround the emission area EMA of each pixel PXL and may constitute a pixel definition layer that partitions the emission area EMA of the pixel PXL. In a process of supplying the light-emitting elements LD to the emission region EMA, the bank BNK may be a dam structure that may perform control to prevent a solution, in which the light-emitting elements LD are mixed, from flowing into the emission area EMA of the adjacent pixel PXL or to supply a certain or predetermined amount of the solution to each emission area EMA.

The light-emitting elements LD may be supplied and aligned in the emission area EMA of each pixel PXL in which the first insulating layer INS1 may be formed. As an example, the light-emitting elements LD may be supplied (or introduced) to the emission area EMA through an inkjet method or the like within the spirit and the scope of the disclosure. The light-emitting elements LD may be aligned between the first electrode EL1 and the second electrode EL2 by a certain or predetermined alignment signal (or alignment voltage) applied to each of the first and second electrodes EL1 and EL2.

Each of the light-emitting elements LD may include the first end portion EP1 and the second end portion EP2 in the length L direction parallel to the first direction DR1. Each of the light-emitting elements LD may include a light-emitting stack pattern 10 and an insulating film 14 surrounding an outer circumferential surface (or surface) thereof. The light-emitting stack pattern 10 may include the first semiconductor layer 11, the first barrier layer 16, the active layer 12, the second barrier layer 17, the second semiconductor layer 13, and the additional electrode 15 which may be sequentially stacked in the length L direction of each light-emitting element LD parallel to the first direction DR1. In an embodiment, the first semiconductor layer 11 may include an n-type semiconductor layer doped with an n-type dopant, and the second semiconductor layer 13 may include a p-type semiconductor layer doped with a p-type dopant.

The second insulating layer INS2 may be provided and/or formed and/or disposed on each of the light-emitting elements LD. The second insulating layer INS2 may be provided and/or formed and/or disposed on the light-emitting elements LD aligned between the first electrode EL1 and the second electrode EL2, thereby partially covering or overlapping an outer circumferential surface (or surface) of each of the light-emitting elements LD and externally exposing the first end portion EP1 and the second end portion EP2 of each of the light-emitting elements LD.

The second insulating layer INS2 may be formed as a single-film or a multi-film and may include an inorganic insulating film including at least one inorganic material or an organic insulating film including at least one organic material. The second insulating layer INS2 may include the inorganic insulating film that may be advantageous in protecting the active layer 12 of each of the light emitting elements LD from external oxygen, moisture, or the like within the spirit and the scope of the disclosure. However, the disclosure is not limited thereto. The second insulating layer INS2 may be formed as an organic insulating film including an organic material according to design conditions of a display device to which the light-emitting elements LD are applied. After the alignment of the light-emitting elements LD is completed in the pixel area PXA of each of the pixels PXL, the second insulating layer INS2 may be formed or disposed on the light-emitting elements LD to prevent the light-emitting elements LD from deviating from positions at which the light-emitting elements LD are aligned.

In a case that an empty gap (or space) may be present between the first insulating layer INS1 and the light-emitting elements LD before the second insulating layer INS2 is formed, the empty gap may be filled with the second insulating layer INS2 in a process of forming the second insulating layer INS2. In this case, the second insulating layer INS2 may be formed as an organic insulating film that may be advantageous in filling the empty gap between the first insulating layer INS1 and the light-emitting elements LD.

The first contact electrode CNE1 may be provided and/or formed and/or disposed on the first electrode EL1 to electrically and/or physically stably electrically connect the first electrode EL1 and one or an end portion of the first and second end portions EP1 and EP2 of the light-emitting elements LD, for example, the second end portion EP2.

The first contact electrode CNE1 may be provided and/or formed and/or disposed on the first electrode EL1 and the second end portion EP2 of each of the light-emitting elements LD. The first contact electrode CNE1 may be disposed to be in electrical contact with the first electrode EL1 on a region of the first electrode EL1 which may not be covered or overlapped by the first insulating layer INS1. According to embodiments, in a case that a conductive capping layer (not illustrated) may be disposed on the first electrode EL1, the first contact electrode CNE1 may be disposed on the conductive capping layer to be electrically connected to the first electrode EL1 through the conductive capping layer. The above-described conductive capping layer may protect the first electrode EL1 from defects or the like generated a process of manufacturing a display device and concurrently may further intensify adhesion between the first electrode EL1 and the pixel circuit layer PCL. The conductive capping layer may include a transparent conductive substance (or material) such as indium zinc oxide (IZO).

For example, the first contact electrode CNE1 may be disposed on the second end portion EP2 of each of the light-emitting elements LD to be in electrical contact with the second end portion EP2 of each of the light-emitting elements LD adjacent to the first electrode ELL For example, the first contact electrode CNE1 may be disposed to cover or overlap the second end portion EP2 of each of the light-emitting elements LD and at least one or a region of the first electrode EL1 corresponding thereto.

The second contact electrode CNE2 may be provided and/or formed and/or disposed on the second electrode EL2 to electrically and/or physically stably electrically connect the second electrode EL2 and one or an end portion of the first and second end portions EP1 and EP2 of the light-emitting elements LD, for example, the first end portion EP1.

The second contact electrode CNE2 may be provided and/or formed and/or disposed on the second electrode EL2 and the first end portion EP1 of each of the light-emitting elements LD. The second contact electrode CNE2 may be disposed to be in electrical contact with the second electrode EL2 on a region of the second electrode EL2 which may not be covered or overlapped by the first insulating layer INS1. According to embodiments, in a case that a conductive capping layer may be disposed on the second electrode EL2, the second contact electrode CNE2 may be disposed on the conductive capping layer to be electrically connected to the second electrode EL2 through the conductive capping layer.

For example, the second contact electrode CNE2 may be disposed on the first end portion EP1 of each of the light-emitting elements LD to be in electrical contact with the first end portion EP1 of each of the light-emitting elements LD adjacent to the second electrode EL2. For example, the second contact electrode CNE2 may be disposed to cover or overlap the first end portion EP1 of each of the light-emitting elements LD and at least one or a region of the second electrode EL2 corresponding thereto.

The first and second contact electrodes CNE1 and CNE2 may be made of various transparent conductive materials to allow light, which is emitted from each of the light-emitting elements LD and is reflected by the first and second electrodes EL1 and EL2, to travel in an image display direction of a display device without loss. As an example, the first and second contact electrodes CNE1 and CNE2 may include at least one selected from various transparent conductive substances (materials) such as indium tin oxide (ITO), indium zinc oxide (IZO), zinc oxide (ZnO), indium gallium zinc oxide (IGZO), and indium tin zinc oxide (ITZO) and may be substantially transparent or semitransparent to satisfy desired transmittance (or transmittancy). However, the material of the first and second contact electrodes CNE1 and CNE2 is not limited to the above-described embodiment. According to embodiments, the first and second contact electrodes CNE1 and CNE2 may be made of various opaque conductive substances (or materials). The first and second contact electrodes CNE1 and CNE2 may be formed as a single-film or a multi-film.

The first contact electrode CNE1 and the second contact electrode CNE2 may be disposed to be spaced apart from each other in the first direction DR1. As an example, the first contact electrode CNE1 and the second contact electrode CNE2 may be disposed to be spaced apart from each other by a certain or predetermined interval on the second insulating layer INS2 on the light-emitting elements LD.

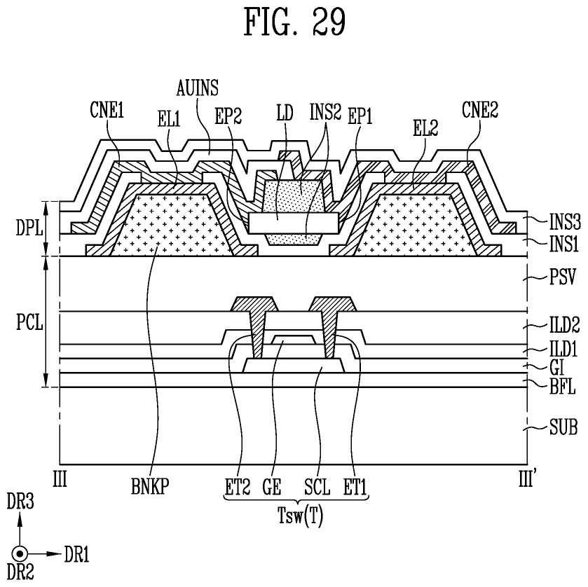

The first contact electrode CNE1 and the second contact electrode CNE2 may be provided or disposed on the same layer. In this case, the first contact electrode CNE1 and the second contact electrode CNE2 may be formed using the same conductive material through the same process, but the disclosure is not limited thereto. According to embodiments, the first contact electrode CNE1 and the second contact electrode CNE2 may be formed through different processes and provided or disposed on different layers. This will be described below with reference to FIG. 29.

The third insulating layer INS3 may be provided and/or formed and/or disposed on the first and second contact electrodes CNE1 and CNE2. The third insulating layer INS3 may be an inorganic insulating film including an inorganic material or an organic insulating film including an organic material. As an example, the third insulating layer INS3 may have a structure in which at least one inorganic insulating film and at least one organic insulating film may be alternately stacked. The third insulating layer INS3 may entirely cover or overlap the display element layer DPL to prevent external water or moisture from being introduced into the display element layer DPL including the light-emitting elements LD.

According to embodiments, the display element layer DPL may optionally further include an optical layer in addition to the third insulating layer INS3. As an example, the display element layer DPL may further include a color conversion layer including color conversion particles that may convert light emitted from the light-emitting elements LD into a specific or predetermined color of light.

According to an embodiment, at least one overcoat layer (for example, a layer that planarizes an upper surface of the display element layer DPL) may be further disposed on the third insulating layer INS3.

The light-emitting stack pattern 10 of each light-emitting element LD may include the first semiconductor layer 11, the first barrier layer 16, the active layer 12, the second barrier layer 17, the second semiconductor layer 13, and the additional electrode 15 which may be sequentially stacked from the first end portion EP1 and the second end portion EP2 in the length L direction of the corresponding light-emitting element LD. In an embodiment, the additional electrode 15 may be made of a transparent conductive material having certain or predetermined transmittance.

Each of the first and second barrier layers 16 and 17 may include an oxide layer, which may be an oxidized region.

As illustrated in FIG. 24, the first barrier layer 16 may be divided or may include into a second region 16_2 which may include an oxide layer and may be positioned or disposed at an edge of a corresponding barrier layer and a first region 16_1 which may not include an oxide layer and may be positioned at a central portion of the corresponding barrier layer. The first region 16_1 may be a region of the first barrier layer 16 which may not be in contact with the insulating film 14, and the second region 16_2 may be the other region of the first barrier layer 16 which may be in direct contact with an inner side surface 14d of the insulating film 14. The first region 16_1 and the second region 16_2 may have the same thickness in the length L direction of the light-emitting element LD parallel to the first direction DR1. As an example, a thickness d1 of the first region 16_1 and a thickness d2 of the second region 16_2 may be the same or may be about the same.

The first region 16_1 of the first barrier layer 16 may serve as a barrier to prevent the reverse flow of electrons from the active layer 12 to the first semiconductor layer 11. The second region 16_2 of the first barrier layer 16 may have relatively high resistance and a relatively low refractive index as compared with the non-oxidized first region 16_1 and thus may be used as an insulating layer. The second region 16_2 of the first barrier layer 16 may form a double insulating layer together with the insulating film 14 covering or overlapping a surface of the first barrier layer 16.

For example, as illustrated in FIG. 24, the second barrier layer 17 may be divided into or may include a fourth region 17_2 which may include an oxide layer and may be positioned or disposed at an edge of a corresponding barrier layer and a third region 17_1 which may not include an oxide layer and may be positioned or disposed at a central portion of the corresponding barrier layer. The third region 17_1 may be a region of the second barrier layer 17 which may not be in contact with the insulating film 14, and the fourth region 17_2 may be the other region of the second barrier layer 17 which may be in direct contact with the inner side surface 14d of the insulating film 14. The third region 17_1 and the fourth region 17_2 may have the same thickness in the length L direction of the light-emitting element LD parallel to the first direction DR1. As an example, a thickness d3 of the third region 17_1 and a thickness d4 of the fourth region 17_2 may be the same or may be about the same.

The third region 17_1 of the second barrier layer 17 may serve as a barrier to prevent the reverse flow of holes from the active layer 12 to the second semiconductor layer 13. The fourth region 17_2 of the second barrier layer 17 may have relatively high resistance and a relatively low refractive index as compared with the non-oxidized third region 17_1 and thus may be used as an insulating layer. The fourth region 17_2 of the second barrier layer 17 may form a double insulating layer together with the insulating film 14 covering or overlapping a surface of the second barrier layer 17.

As in the above-described embodiment, in a case that each of the light-emitting elements LD may include the first barrier layer 16 including the oxide layer (for example, the second region 16_2) and the second barrier layer 17 including the oxide layer (for example, the fourth region 17_2), surface resistance in the undoped region A of the light-emitting stack pattern 10 included in the corresponding light-emitting element LD may be relatively increased. Surface resistance of the second region 16_2 of the first barrier layer 16 and the fourth region 17_2 of the second barrier layer 17, which each may be in contact with the inner side surface 14d of the insulating film 14 in the undoped region A, may be relatively increased. Accordingly, a leakage current path on a surface of the light-emitting stack pattern 10 (or corresponding light-emitting element LD) may be blocked to minimize a surface leakage current, thereby improving luminous efficiency of each light-emitting element LD.

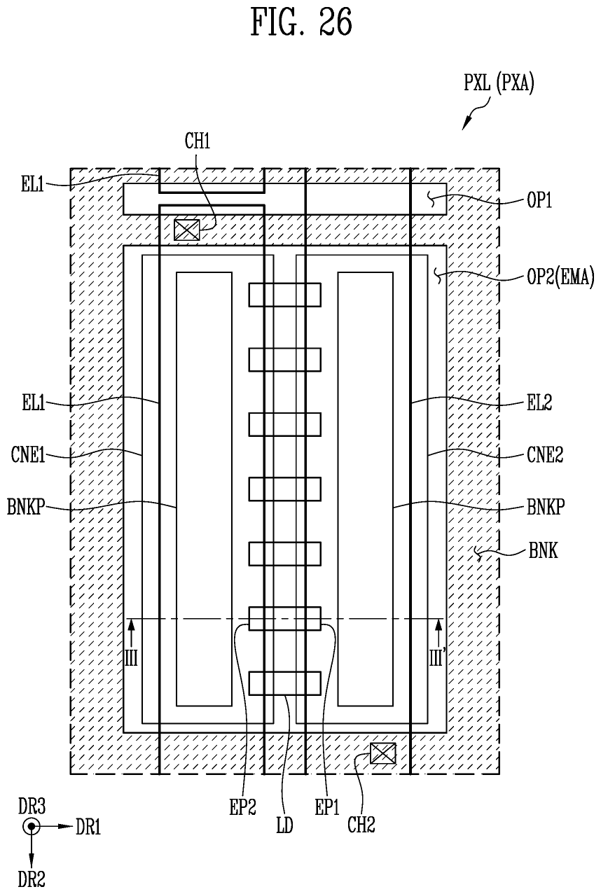

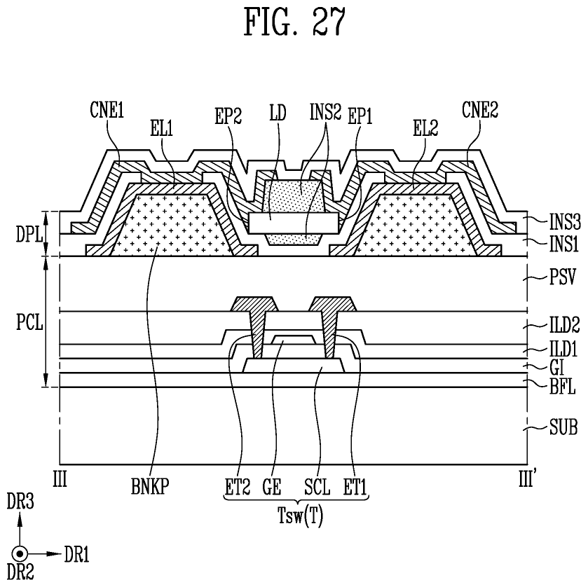

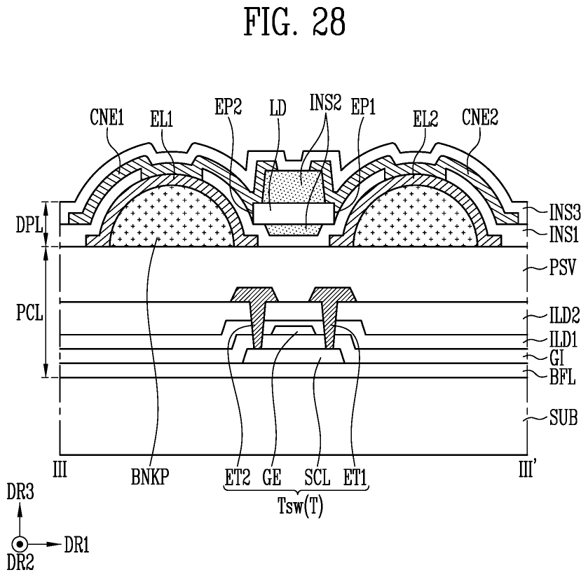

FIG. 26 is a schematic plan view illustrating a pixel according to an embodiment. FIG. 27 is a schematic cross-sectional view taken along line III-III′ of FIG. 26. FIG. 28 is a schematic cross-sectional view corresponding to line III-III′ of FIG. 27 which illustrates a bank pattern of FIG. 27 that may be implemented according to an embodiment. FIG. 29 is a schematic cross-sectional view corresponding to line III-III′ of FIG. 26 which illustrates first and second contact electrodes of FIG. 27 that may be implemented according to an embodiment.

A pixel PXL illustrated in FIGS. 26 to 29 may have a configuration that may be substantially the same or similar to that of the pixel illustrated in FIGS. 21 to 25 except that a bank pattern BNKP may be disposed between a passivation layer PSV and each of first and second electrodes EL1 and EL2.

Accordingly, in relation to the pixel of FIGS. 26 to 29, differences from the above-described embodiment will be mainly described in order to avoid redundant descriptions.

Referring to FIGS. 26 to 29, a support member may be positioned or disposed between each of the first and second electrodes EL1 and EL2 and the passivation layer PSV. As an example, as illustrated in FIGS. 27 to 29, the bank pattern BNKP may be positioned or disposed between each of the first and second electrodes EL1 and EL2 and the passivation layer PSV.

The bank pattern BNKP may be positioned or disposed in an emission area EMA of a pixel area PXA in each pixel PXL, from which light is emitted. In order to guide light emitted from light-emitting elements LD in an image display direction of a display device, the bank pattern BNKP may be a support member which supports each of the first and second electrodes EL1 and EL2 to change a surface profile (or shape) of each of the first and second electrodes EL1 and EL2.

The bank pattern BNKP may be provided or disposed between the passivation layer PSV and the first and second electrodes EL1 and EL2 in the emission region EMA of the corresponding pixel PXL.

The bank pattern BNKP may be an inorganic insulating film including an inorganic material or an organic insulating film including an organic material. According to embodiments, the bank pattern BNKP may include a single organic insulating film and/or a single inorganic insulating film, but the disclosure n is not limited thereto. According to embodiments, the bank pattern BNKP may be provided in the form of a multi-film in which at least one organic insulating film and at least one inorganic insulating film may be stacked. However, the material of the bank pattern BNKP is not limited to the above-described embodiment, and according to embodiments, the bank pattern BNKP may include a conductive material.

The bank pattern BNKP may have a cross section having a substantially trapezoidal shape of which a width may be gradually decreased upward from one or a surface (for example, an upper surface) of the passivation layer PSV in a third direction DR3, but the disclosure is not limited thereto. According to embodiments, as shown in FIG. 28, the bank pattern BNKP may have a substantially curved surface including a cross section with a substantially semi-elliptical shape or a substantially semicircular shape (or substantially hemisphere shape) of which a width may be gradually decreased upward from one or a surface of the passivation layer PSV in the third direction DR3. When viewed in a cross section, the shape of the bank pattern BNKP is not limited to the above-described embodiments and may be variously changed within a range capable of improving efficiency of light emitted from each of the light-emitting elements LD.

Each of the first and second electrodes EL1 and EL2 may be provided and/or formed and/or disposed on the corresponding bank pattern BNKP. In this case, each of the first and second electrodes EL1 and EL2 may have a surface profile substantially corresponding to the shape of the bank pattern BNKP disposed thereunder when viewed in a cross section. Accordingly, light emitted from the light-emitting elements LD may be reflected by each of the first and second electrodes EL1 and EL2 to further travel in an image display direction of a display device. Each of the bank pattern BNKP and the first and second electrodes EL1 and EL2 may be used as a reflective member to improve light efficiency of a display device by guiding light emitted from the light-emitting elements LD in a desired direction. Accordingly, luminous efficiency of the light-emitting elements LD may be further improved.

A first contact electrode CNE1 and a second contact electrode CNE2 may be disposed to be spaced apart from each other in a first direction DR1 in a plan view. As an example, the first contact electrode CNE1 and the second contact electrode CNE2 may be disposed to be spaced apart from each other by a certain or predetermined interval on a second insulating layer INS2 on the light-emitting elements LD. The first contact electrode CNE1 and the second contact electrode CNE2 may be provided or disposed on the same layer and may be formed through the same process. However, the disclosure is not limited thereto, and according to embodiments, the first and second contact electrodes CNE1 and CNE2 may be provided or disposed on different layers and may be formed through different processes. In this case, as illustrated in FIG. 29, an additional insulating layer AUINS may be provided and/or formed and/or disposed between the first contact electrode CNE1 and the second contact electrode CNE2. The additional insulating layer AUINS may be provided or disposed on the first contact electrode CNE1 to prevent the first contact electrode CNE1 from being externally exposed, thereby preventing corrosion of the first contact electrode CNE1. The additional insulating layer AUINS may include an inorganic insulating film made of an inorganic material or an organic insulating film made of an organic material. As an example, the additional insulating layer AUINS may include at least one selected from metal oxides such as silicon nitride (SiNₓ), silicon oxide (SiOₓ), silicon oxynitride (SiOₓN_{y}), and aluminum oxide (AlOₓ), but the disclosure is not limited thereto. For example, the additional insulating layer AUINS may be formed as a single-film or a multi-film.

A third insulating layer INS3 may be provided and/or formed and/or disposed on the first and second contact electrodes CNE1 and CNE2. The third insulating layer INS3 may be an inorganic insulating film including an inorganic material or an organic insulating film including an organic material. As an example, the third insulating layer INS3 may have a structure in which at least one inorganic insulating film and at least one organic insulating film may be alternately stacked. The third insulating layer INS3 may entirely cover or overlap the display element layer DPL to prevent external water or moisture from being introduced into the display element layer DPL including the light-emitting elements LD. According to embodiments, at least one overcoat layer (for example, a layer that planarizes an upper surface of the display element layer DPL) may be further disposed on the third insulating layer INS3.

In a light-emitting element, a method of manufacturing the light-emitting element, and a display device including the light-emitting element, since a barrier layer including an oxide layer may be disposed between an active layer and a p-type semiconductor layer and between an active layer and an n-type semiconductor layer, it may be possible to minimize a surface leakage current due to damage to a surface exposed during a manufacturing process of the light-emitting element, thereby manufacturing the light-emitting element having improved luminous efficiency.

The effects according to an embodiment are not limited by the above-described contents, and more various effects are included in the specification.

Although embodiments have been described, it is understood that the disclosure should not be limited to these embodiments but various changes and modifications may be made by one of ordinary skill in the art within the spirit and scope of the disclosure as hereinafter claimed.

Therefore, the technical scope of the disclosure is not limited to the embodiments described herein, but should be determined by the claims.

What is claimed is:

1. A light-emitting element comprising:
a first end portion and a second end portion disposed in a length direction of the light-emitting element;
a first semiconductor layer disposed at the first end portion;
an active layer disposed on the first semiconductor layer;
a second semiconductor layer disposed on the active layer;
a first barrier layer disposed between the active layer and the first semiconductor layer, the first barrier layer including a first region and a second region; and
an insulating film that surrounds an outer circumferential surface of each of the first semiconductor layer, the active layer, the first barrier layer, and the second semiconductor layer, wherein
the first region of the first barrier layer includes a semiconductor layer having an aluminum composition higher than an aluminum composition of the first semiconductor layer, the active layer, and the second semiconductor layer, and
the second region of the first barrier layer includes an oxide layer.

2. The light-emitting element of claim 1, wherein
the first semiconductor layer includes an n-type semiconductor layer doped with an n-type dopant,
the second semiconductor layer includes a p-type semiconductor layer doped with a p-type dopant, and
the active layer and the first barrier layer are semiconductor layers that are not doped with the n-type dopant or the p-type dopant.

3. The light-emitting element of claim 2, further comprising a second barrier layer disposed between the second semiconductor layer and the active layer, the second barrier layer including a third region and a fourth region,
wherein the second barrier layer is a semiconductor layer which is not doped with the n-type dopant or the p-type dopant.

4. The light-emitting element of claim 3, wherein
the third region of the second barrier layer includes a second semiconductor layer having an aluminum composition higher than the aluminum composition of the first semiconductor layer, the active layer, and the second semiconductor layer,
the fourth region of the second barrier layer includes an oxide layer, and
the third region and the fourth region have a same thickness in the length direction of the light-emitting element.

5. The light-emitting element of claim 4, wherein the second region and the fourth region have a same width or different widths in a direction intersecting the length direction of the light-emitting element.

6. The light-emitting element of claim 4, wherein the second region and the fourth region have a same thickness or different thicknesses in the length direction of the light-emitting element.

7. The light-emitting element of claim 3, wherein the first barrier layer and the second barrier layer include a same material.

8. The light-emitting element of claim 4, wherein the first region of the first barrier layer and the third region of the second barrier layer include an AlInP layer including aluminum, indium, and phosphorus or an AlGaAs layer including aluminum, gallium, and arsenic.

9. The light-emitting element of claim 1, wherein the first region of the first barrier layer and the second region of the first barrier layer have a same thickness in the length direction of the light-emitting element.

10. The light-emitting element of claim 1, further comprising an electrode disposed on the second semiconductor layer at the second end portion of the light-emitting element.

11. A method of manufacturing a light-emitting element, the method comprising:
forming a first semiconductor layer, a first barrier layer, an active layer, a second barrier layer, a second semiconductor layer, and an electrode on a substrate to form a light-emitting stack;
vertically etching the light-emitting stack to form at least one light-emitting stack pattern and externally exposing one region of the first semiconductor layer;
performing heat treatment on the at least one light-emitting stack pattern so that each of the first barrier layer and the second barrier layer includes a first region and a second region, the first region and the second region including different materials;
forming an insulating material layer on the at least one light-emitting stack pattern and vertically etching the insulating material layer to form an insulating film surrounding a surface of the light-emitting stack pattern; and
separating the at least one light-emitting stack pattern surrounded by the insulating film from the substrate to form a light-emitting element, wherein
the light-emitting element includes the first semiconductor layer, the first barrier layer, the active layer, the second barrier layer, the second semiconductor layer, and the electrode disposed in a length direction of the light-emitting element,
the first region of each of the first barrier layer and the second barrier layer includes a semiconductor layer having an aluminum composition higher than an aluminum composition of the first semiconductor layer, the active layer, and the second semiconductor layer, and
the second region of each of the first barrier layer and the second barrier layer includes an oxide layer.

12. The method of claim 11, wherein
the first semiconductor layer includes an n-type semiconductor layer doped with an n-type dopant,
the second semiconductor layer includes a p-type semiconductor layer doped with a p-type dopant, and
the first barrier layer, the active layer, and the second barrier layer are semiconductor layers which are not doped with the n-type dopant or the p-type dopant.

13. The method of claim 12, wherein the second region of the first barrier layer and the second region of the second barrier layer have a same width or different widths in a direction intersecting the length direction of the light-emitting element.

14. The method of claim 12, wherein the second region of the first barrier layer and the second region of the second barrier layer have a same thickness or different thicknesses in the length direction of the light-emitting element.

15. The method of claim 12, wherein the forming of the light-emitting stack includes:
forming the first semiconductor layer on the substrate;
forming the first barrier layer on the first semiconductor layer;
forming the active layer on the first barrier layer;
forming the second barrier layer on the active layer;
forming the second semiconductor layer on the second barrier layer; and
forming the electrode on the second semiconductor layer.

16. The method of claim 12, wherein the first region of each of the first barrier layer and the second barrier layer includes an AlInP layer including aluminum, indium, and phosphorus or an AlGaAs layer including aluminum, gallium, and arsenic.

17. The method of claim 11, wherein
the first barrier layer and the second barrier layer include a same material, and
the first region of each of the first barrier layer and the second barrier layer has a same thickness as the second region of the respective barrier layer.

18. A display device comprising:
a first electrode and a second electrode disposed on a substrate in a first direction and extending in a second direction different from the first direction, the first electrode and the second electrode being spaced apart from each other; and
a plurality of light-emitting elements disposed between the first electrode and the second electrode, wherein
each of the plurality of light-emitting elements includes:
a first end portion and a second end portion disposed in a length direction of the light-emitting element;
a first semiconductor layer disposed at the first end portion;
a first barrier layer disposed on the first semiconductor layer and including a first region and a second region;
an active layer disposed on the first barrier layer;
a second barrier layer disposed on the active layer and including a third region and a fourth region;
a second semiconductor layer disposed on the second barrier layer;
a third electrode disposed on the second semiconductor layer; and
an insulating film surrounding an outer circumferential surface of each of the first semiconductor layer, the first barrier layer, the active layer, the second barrier layer, the second semiconductor layer, and the third electrode,
the first region and the third region include a semiconductor layer having an aluminum composition higher than an aluminum composition of the first semiconductor layer, the active layer, and the second semiconductor layer, and
the second region and the fourth region include an oxide layer.

19. The display device of claim 18, wherein
the first semiconductor layer includes an n-type semiconductor layer doped with an n-type dopant,
the second semiconductor layer includes a p-type semiconductor layer doped with a p-type dopant,
the first barrier layer, the active layer, and the second barrier layer are undoped regions,
the first region and the second region have a same thickness in the length direction of the light-emitting element, and
the third region and the fourth region have a same thickness in the length direction of the light-emitting element.

20. The display device of claim 19, further comprising:
a first contact electrode disposed on the first electrode and one of the first end portion and the second end portion of each of the plurality of light-emitting elements; and
a second contact electrode disposed on the second electrode and the other of the first end portion and the second end portion of each of the plurality of light-emitting elements, wherein
the first contact electrode is electrically connected to the first electrode, and
the second contact electrode is electrically connected to the second electrode.
